(19) United States
(12) Patent Application Publication
(10) Pub. No.: US 2025/0072232 A1
(43) Pub. Date: Feb. 27, 2025

(54) DISPLAY APPARATUS AND CONTROL METHOD THEREOF

(71) Applicant: Samsung Display Co., Ltd., Yongin-Si (KR)

(72) Inventors: Jinsoo Jung, Yongin-si (KR); Seokgyu Yoon, Yongin-si (KR); Minsoo Choi, Yongin-si (KR)

(21) Appl. No.: 18/635,955

(22) Filed: Apr. 15, 2024

(30) Foreign Application Priority Data
Aug. 22, 2023 (KR) 10-2023-0110129

(51) Int. Cl. H10K 59/13; G06V 40/13; H10K 39/34; H10K 59/121

(52) U.S. Cl. CPC H10K 59/13; G06V 40/1318; H10K 39/34; H10K 59/1213

(57) ABSTRACT

A display apparatus includes a substrate, a pixel arranged in a display area of the substrate and including a light-emitting diode configured to emit light in a first mode, and a photo sensor arranged in the display area of the substrate and configured to receive, in a second mode, light reflected from an external object and receive external light in a third mode. The first mode is triggered by a signal to display an image, the second mode is triggered by reflection from the external object, and the third mode is triggered by absence of the signal to display an image and reflection from the external object.

### CROSS-REFERENCE TO RELATED APPLICATION

This application is based on and claims priority, under 35 U.S.C. § 119, to Korean Patent Application No. 10-2023-0110129, filed on Aug. 22, 2023 in the Korean Intellectual Property Office, the disclosure of which is incorporated by reference herein in its entirety.

### BACKGROUND

### 1. Field

One or more embodiments relate to a display apparatus and a control method thereof.

### 2. Description of the Related Art

Display apparatuses include pixels, and each pixel may include a light-emitting diode and a transistor driving the light-emitting diode. Also, display apparatuses include photo sensors, and each photo sensor may include a light-receiving element and a transistor driving the light-receiving element.

### SUMMARY

One or more embodiments include a method of charging a display apparatus by using a light-receiving element.

The effects of the embodiments are not limited to the aforementioned description, and other effects may be clearly understood by one of ordinary skill in the art from the embodiments to be described hereinafter.

Additional aspects will be set forth in part in the description which follows and, in part, will be apparent from the description, or may be learned by practice of the presented embodiments of the disclosure.

According to one or more embodiments, a display apparatus includes a substrate, a pixel arranged in a display area of the substrate and including a light-emitting diode configured to emit light in a first mode, and a photo sensor arranged in the display area of the substrate and configured to receive light reflected from an external object in a second mode, and receive external light in a third mode. The first mode is triggered by a signal to display an image, the second mode is triggered by a reflection from the external object, and the third mode is triggered by an absence of the signal to display an image and a reflection from the external object.

The display apparatus may further include a readout circuit arranged in a peripheral area of the substrate and configured to process an electrical signal corresponding to an amount of the light received by the light-receiving element in the second mode.

The display apparatus may further include a charge controller arranged in the peripheral area of the substrate and configured to store and control an electrical signal corresponding to an amount of the external light received by the light-receiving element in the third mode and a battery configured to store an output voltage of the charge controller.

The light reflected from the external object may include light emitted from the light-emitting diode in the second mode and then reflected off the external object, wherein the light emitted from the light-emitting diode may include green light.

The photo sensor may include a sensing circuit connected to the light-receiving element, the light-receiving element may include a first electrode, a second electrode, and an intermediate layer between the first electrode and the second electrode, and the sensing circuit may include a first transistor including a gate electrode connected to a first electrode of the light-receiving element, a second transistor connected between the first transistor and a readout line connected to the readout circuit, a reset transistor connected between a reset voltage line and the first electrode of the light-receiving element, and a third transistor connected between the first electrode of the light-receiving element and the readout line.

The reset transistor may be turned on in response to a first reset signal in the second mode, the second transistor may be turned on in response to a first control signal, and a photocurrent output from the first transistor may be transmitted to the readout line. In the third mode, the third transistor may be turned on in response to a second reset signal, and a photocurrent corresponding to a voltage between the first electrode and a second electrode of the light-receiving element may be transmitted to the readout line.

The photo sensor may operate in the third mode when the light-emitting diode included in the pixel is not emitting light and the photo sensor is not receiving the light reflected from the external object.

The light-receiving element may include an organic photodiode (OPD).

According to one or more embodiments, a display apparatus includes a display panel including a plurality of pixels and a plurality of photo sensors, a driving circuit configured to drive the plurality of pixels and the plurality of photo sensors, a controller configured to control the display panel to display an image according to light emission from the plurality of pixels in a first mode, control the plurality of photo sensors to sense light reflected from a fingerprint in a second mode, and control external light sensed by the plurality of photo sensors to charge a battery in a third mode, a readout circuit configured to receive a plurality of light sensing signals of the plurality of photo sensors and perform signal processing to obtain fingerprint information in the second mode, and the battery configured to store a voltage corresponding to the plurality of light sensing signals of the plurality of photo sensors in the third mode.

The display apparatus may further include a charge controller configured to control a voltage corresponding to the plurality of light sensing signals of the plurality of photo sensors in the third mode.

The controller may be configured to control the display apparatus to operate in the third mode in the absence of a signal to operate in the first mode or the second mode.

The plurality of photo sensors and the charge controller may be connected by a switch transistor that is turned on in response to a control signal from the controller.

According to one or more embodiments, there is provided a method of controlling operation of a display apparatus including a plurality of pixels and a plurality of photo sensors, the method including controlling the display apparatus to display an image according to light emission from the plurality of pixels in a first mode, controlling the display apparatus to sense light reflected from an external object by using the plurality of photo sensors and to process an electrical signal corresponding to an amount of the light in a second mode, and controlling the display apparatus to sense external light by using the plurality of photo sensors and to charge a voltage corresponding to an amount of external light to a battery in a third mode.

The controlling in the third mode may include controlling the display apparatus to operate in the third mode in the absence of a signal to operate in either the first mode or the second mode.

In the second mode, light emitted from a plurality of first pixels among the plurality of pixels may be reflected off the external object, wherein the plurality of first pixels are arranged adjacent to the external object and emit a certain color of light, and the light emitted from the plurality of first pixels may include green light.

Each of the plurality of photo sensors may include a light-receiving element and a sensing circuit connected to the light-receiving element, the light-receiving element may include a first electrode, a second electrode, and an intermediate layer between the first electrode and the second electrode, and the sensing circuit may include a first transistor including a gate electrode connected to a first electrode of the light-receiving element, a second transistor connected between the first transistor and a readout line connected to the readout circuit, a reset transistor connected between a reset voltage line and the first electrode of the light-receiving element, and a third transistor connected between the first electrode of the light-receiving element and the readout line.

In the second mode, the reset transistor may be turned on in response to a first reset signal, the second transistor may be turned on in response to a first control signal, and a photocurrent that is output by the first transistor may be transmitted to the readout line.

In the third mode, the third transistor may be turned on in response to a second reset signal, and a photocurrent corresponding to a voltage between the first electrode and the second electrode of the light-receiving element may be transmitted to the readout line.

The light-receiving element may include an OPD.

In addition, there may be further provided a computer program stored on a computer-readable recording medium to implement the disclosure.

Moreover, there may be further provided a computer-readable recording medium that records a computer program for executing a method for implementing the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 schematically shows a display apparatus according to an embodiment;

FIG. 2 schematically shows components of a display apparatus according to an embodiment;

FIG. 3 is a detailed circuit diagram of a pixel and a photo sensor, according to an embodiment;

FIG. 4 shows signals in a first mode to a third mode, according to an embodiment;

FIG. 5 is a schematic cross-sectional view showing a principle of detecting a fingerprint as a display apparatus operates in a second mode, according to an embodiment;

FIG. 6 schematically shows components of a display apparatus according to an embodiment;

FIG. 7 is a flowchart of operations in a first mode to a third mode, according to an embodiment.

FIG. 8 is a diagram showing an arrangement structure of pixels and a photo sensor, according to an embodiment;

FIG. 9 is a schematic cross-sectional view of a portion of a display apparatus, according to an embodiment; and

FIGS. 10A to 10C are diagrams for explaining that a photo sensor functions as a battery even when no voltage is applied, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be shown in the drawings and described in detail in the written description. The attached drawings for illustrating embodiments are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

Throughout the specification, like reference numerals denote like elements. The disclosure does not encompass all elements of embodiments, and descriptions of general content in the field to which the disclosure pertains or repeated descriptions in embodiments are omitted. The terms “unit,” “module,” “member,” and “block” used herein may be implemented as software or hardware, and according to embodiments, a plurality of “units,” “modules,” “members,” and “blocks” may be implemented as one component, or one “unit,” “module,” “member,” and “block” includes various components.

Throughout the specification, when a portion is “connected to” another portion, this connection includes a direct connection and an indirect connection, and the indirect connection includes a connection made through a wireless communication network.

It will be further understood that the terms “comprises” and/or “comprising” used herein specify the presence of stated features or components, but do not preclude the presence or addition of one or more other features or components.

It will be understood that the terms “first,” “second,” etc. may be used herein to distinguish one component from another, and these components should not be limited by these terms. The terms are only used to distinguish one component from another.

As used herein, the singular forms “a,” “an” and “the” are intended to include the plural forms as well, unless the context clearly indicates otherwise.

In each operation, reference symbols are used for convenience of explanation and do not describe an order of operations, and unless otherwise specifically stated, the operations may be performed in an order different from the described order.

Hereinafter, one or more embodiments of the disclosure will be described in detail with reference to the accompanying drawings. Like elements in the drawings denote like elements, and repeated descriptions thereof are omitted.

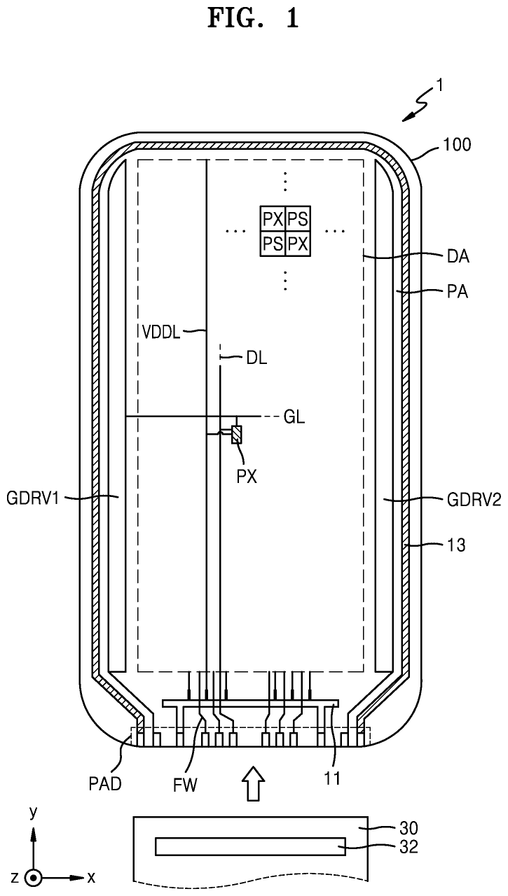

FIG. 1 schematically shows a display apparatus 1 according to an embodiment.

Referring to FIG. 1, the display apparatus 1 may include a display area DA, where images are displayed, and a peripheral area PA outside the display area DA. The display area DA may be entirely surrounded by the peripheral area PA. The display apparatus 1 may include a display panel, and various components forming the display panel may be disposed above a substrate 100. In the substrate 100, the display area DA and the peripheral area PA surrounding the display area DA may be defined.

In the display area DA of the substrate 100, a plurality of pixels PX may be arranged. In the display area DA, a plurality of gate lines GL, a plurality of data lines DL, and the pixels PX connected thereto may be arranged. FIG. 1 shows an example in which the pixel PX is connected to one gate line GL, but one or more embodiments are not limited thereto. The pixel PX may be connected to one or more gate lines GL.

In the display area DA of the substrate 100, a plurality of photo sensors PS may be further arranged. The arrangement and structure of the photo sensors PS are described below in detail.

Pixel circuits driving the pixels PX and sensing circuits driving the photo sensors PS may be electrically connected to outer circuits arranged in the peripheral area PA, respectively. For example, in the peripheral area PA, a first gate driving circuit GDRV1, a second gate driving circuit GDRV2, a pad portion PAD, a driving voltage supply line 11, a common voltage supply line 13, and the like may be arranged.

In an embodiment, the peripheral area PA may be a non-display area where no pixels PX are arranged. In another embodiment, the pixels PX may overlap the outer circuit on at least one corner of the peripheral area PA. Accordingly, a dead space may be reduced, and the display area DA may expand.

The first gate driving circuit GDRV1 may be connected to a plurality of gate lines GL, and gate signals may be respectively applied to the pixel circuits driving the pixels PX through the gate lines GL. The second gate driving circuit GDRV2 may be opposite to the first gate driving circuit GDRV1 with respect to the display area DA and may be substantially parallel to the first gate driving circuit GDRV1. In an embodiment, the pixel circuits of the pixels PX in the display area DA may be electrically connected to the first gate driving circuit GDRV1 and the second gate driving circuit GDRV2. In another embodiment, some of the pixel circuits of the pixels PX in the display area DA may be electrically connected to the first gate driving circuit GDRV1, while others thereof may be electrically connected to the second gate driving circuit GDRV2. The second gate driving circuit GDRV2 may be omitted.

The pad portion PAD may be disposed above one side of the substrate 100. The pad portion PAD may not be covered by an insulating layer and be exposed and thus connected to a display circuit board 30. A display driver 32 may be arranged in the display circuit board 30.

The display driver 32 may include a data driving circuit, and the data driving circuit may be connected to the data lines DL and configured to generate data signals, and the generated data signals may be transmitted to the pixel circuits of the pixels PX through a fan-out line FW and the data line DL connected to the fan-out line FW.

The display driver 32 may include a power supply circuit, and the power supply circuit may supply a driving voltage to the driving voltage supply line 11 and a common voltage to the common voltage supply line 13. The driving voltage may be applied to the pixel circuits of the pixels PX through a driving voltage line VDDL connected to the driving voltage supply line 11, and the common voltage may be applied to an opposite electrode of a display element through the common voltage supply line 13.

The display driver 32 may include a controller, and the controller may generate control signals transmitted to the first gate driving circuit GDRV1, the second gate driving circuit GDRV2, a data driving circuit, and a power supply circuit.

In the display circuit board 30, a readout circuit, a charge controller, etc. electrically connected to the photo sensor PS may be further arranged.

The driving voltage supply line 11 may be connected to the pad portion PAD and may extend on a lower side of the display area DA in an x direction. The common voltage supply line 13 may be connected to the pad portion PAD and have a loop shape with one open side such that the common voltage supply line 13 may partially surround the display area DA.

Part or all of the first gate driving circuit GDRV1 and the second gate driving circuit GDRV2 may be directly formed in the peripheral area PA of the substrate 100 in the process of forming the pixel circuit in the display area DA of the substrate 100. The display driver 32 may be formed as an integrated circuit chip or in the form of an integrated circuit chip and arranged on the display circuit board 30 electrically connected to the pad portion PAD that is arranged on a side of the substrate 100. The display circuit board 30 may be a printed circuit board (PCB) and/or a flexible printed circuit board (FPCB). In another embodiment, the display driver 32 may be directly disposed on the substrate 100 in a Chip On Glass (COG) manner or a Chip On Plastic (COP) manner.

In an embodiment, a plurality of transistors included in the pixel circuits in the display area DA and the outer circuit in the peripheral area PA, for example, a plurality of transistors included in the first gate driving circuit GDRV1 and the second gate driving circuit GDRV2, may each be an N-type oxide thin-film transistor. The transistors included in the outer circuit of the peripheral area PA may be formed simultaneously with the transistors included in the pixel circuits of the display area DA through the same process. In another embodiment, the transistors included in the pixel circuits of the display area DA may each be an N-type oxide thin-film transistor, and the transistors included in the outer circuit of the peripheral area PA may each be a P-type silicon thin-film transistor.

A semiconductor layer of the oxide thin-film transistor may include oxide. The oxide semiconductor may include a Zn-oxide-based material and include Zn oxide, In—Zn oxide, Ga—In—Zn oxide, and the like. In some embodiments, the oxide semiconductor may be an In—Ga—Zn—O (IGZO) semiconductor including metal, such as In and Ga, in ZnO. In an embodiment, the oxide thin-film transistor may be a low temperature polycrystalline oxide (LTPO) thin-film transistor. The silicon thin-film transistor may be a low temperature polysilicon (LTPS) thin-film transistor in which a semiconductor layer includes amorphous silicon, polysilicon, or the like.

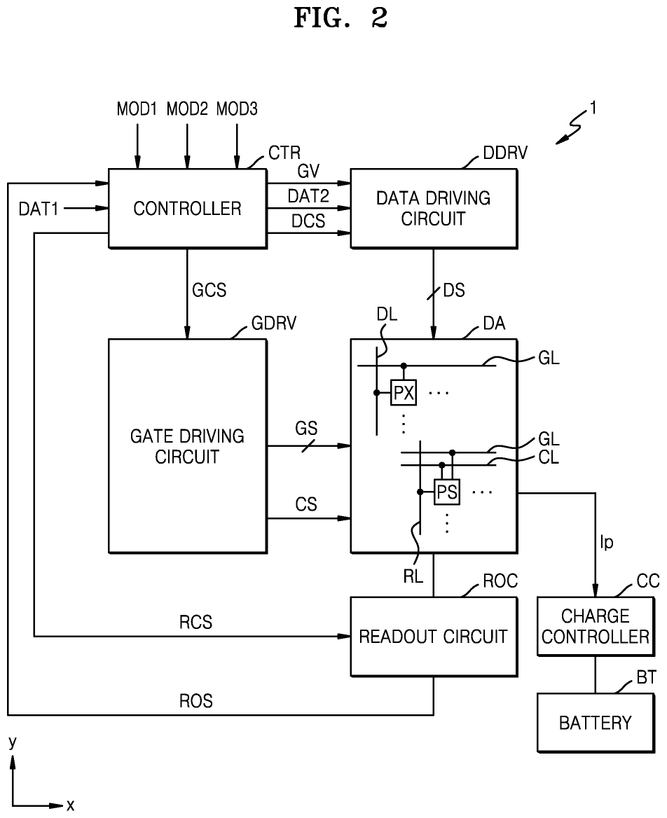

FIG. 2 schematically shows components of a display apparatus according to an embodiment.

Referring to FIG. 2, the display apparatus may include a plurality of pixels PX and a plurality of photo sensors PS arranged in the display area DA, a gate driving circuit GDRV, a data driving circuit DDRV, a readout circuit ROC, a charge controller CC, a controller CTR, and a battery BT arranged in the peripheral area (PA of FIG. 1). A person skilled in the art will understand how to implement the charge controller, the controller, and battery, which are commonly used elements in the field of display devices.

In the display area DA, the pixels PX and signal lines configured to apply electrical signals to the pixels PX may be arranged. Also, in the display area DA, the photo sensors PS and signal lines configured to apply electrical signals to the photo sensors PS may be arranged. The display area DA may be a display area where images are displayed and fingerprints are detected.

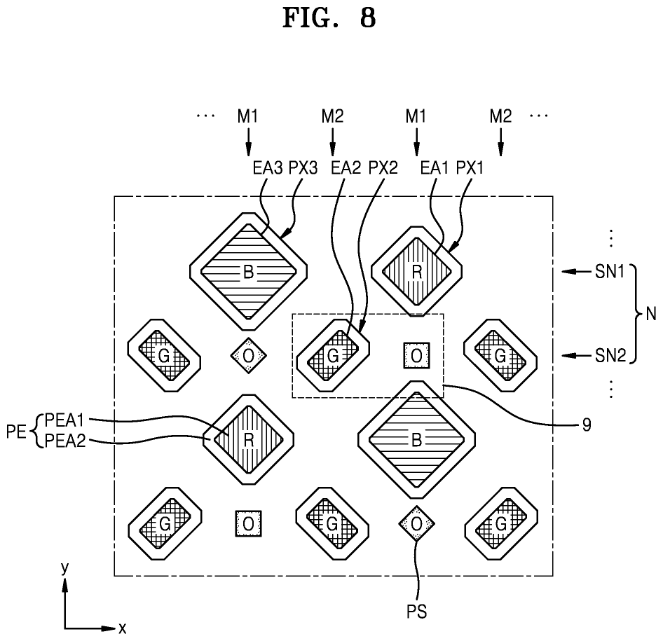

The pixels PX and the photo sensors PS may be repeatedly arranged in an x direction (a row direction) and a y direction (a column direction). The pixels PX and the photo sensors PS may be arranged in various patterns, such as stripe, pentile, mosaic, and diamond, to produce images. The arrangements of the pixels PX and the photo sensors PS according to an embodiment are described below with reference to FIG. 8.

Each pixel PX may be connected to a data line DL and a gate line GL, and each photo sensor PS may be connected to a readout line RL and a control line CL. In an embodiment, the control line CL may be the gate line GL.

For convenience, FIG. 2 shows that one gate line GL is connected to a pixel PX and one control line CL is connected to a photo sensor PS, but according to the number of transistors constituting a pixel circuit and a sensing circuit, each pixel PX may be connected to a plurality of gate lines, and each photo sensor PS may be connected to a plurality of control lines.

The gate driving circuit GDRV may be connected to the gate lines GL and configured to generate gate signals GS in response to control signals GCS transmitted from the controller CTR and sequentially provide the gate signals GS to the gate lines GL. The gate driving circuit GDRV may be connected to the control lines CL and may be configured to generate control signals CS in response to control signals GCS transmitted from the controller CTR and provide the control signals CS to the control lines CL.

The data driving circuit DDRV may be connected to the data lines DL and configured to provide data signals DS in response to control signals DCS transmitted from the controller CTR to the data lines DL. The data driving circuit DDRV may receive, from the controller CTR, gamma voltages GV corresponding to respective gray scales and image data DAT2 and generate data signals DS corresponding to the gray scales.

The readout circuit ROC may be connected to a plurality of readout lines RL arranged in the display area DA, process a light sensing signal received from the photo sensors PS in response to a readout control signal RCS, and provide a processed signal ROS to the controller CTR.

The charge controller CC may be connected to the readout lines RL arranged in the display area DA and receive a photocurrent Ip flowing through the readout lines RL in a third mode (a charging mode) of the display apparatus 1, thus supplying a voltage to the battery BT.

The controller CTR may convert input image data DAT1 that is input from the outside (e.g., a graphics processing unit) to generate the image data DAT2. For example, the controller CTR may convert the input image data DAT1 in an RGB format into the image data DAT2 in a format matching the arrangement of pixels PX in the display area DA. The controller CTR may include a storage medium in which gamma voltages corresponding to gray scales and correction data are recorded.

The controller CTR may generate biometric information from a signal that is output from the readout circuit ROC and may output a signal for the operation of the display apparatus 1, the signal corresponding to the biometric information.

According to an embodiment, upon determining that the display apparatus 1 is not operating in a first mode (a mode in which an image is displayed) because the input image data DAT1 is not input from the outside, and upon determining that the display apparatus 1 is not operating in a second mode (a mode in which a fingerprint is detected) because a touch signal is not sensed from an external object (e.g., a finger), the controller CTR may, by default, control the operation of the photo sensor PS to make the display apparatus 1 operate in a third mode (a charging mode). The determination to not operate in a first mode and the determination to not operate in the second mode may be made sequentially or simultaneously. Accordingly, the photo sensor PS may transmit the photocurrent Ip to the charge controller CC through the readout line RL, and the charge controller CC may control the photocurrent Ip and thus supply a voltage to the battery BT.

The controller CTR may generate the gate control signal GCS, the data control signal DCS, and the readout control signal RCS, based on signals that are input from the outside. The controller CTR may supply the gate control signal GCS to the gate driving circuit GDRV, the data control signal DCS to the data driving circuit DDRV, and the readout control signal RCS to the readout circuit ROC.

FIG. 2 shows that the data driving circuit DDRV, the readout circuit ROC, and the controller CTR are mutually independent, but one or more embodiments are not limited thereto. For example, the data driving circuit DDRV, the readout circuit ROC, and the controller CTR may be realized as one IC (e.g., a driving integrated circuit).

The display apparatus 1 may be a display apparatus, such as an organic light-emitting display apparatus, an inorganic light-emitting display apparatus (or an inorganic EL display apparatus), or a quantum dot light-emitting display apparatus.

The display apparatus 1 may be used as a display screen of various products, for example, a portable electronic apparatus such as a mobile phone, a smartphone, a tablet Personal Computer (PC), a mobile communication terminal, a personal digital assistant, an e-book terminal, a Portable Multimedia Player (PMP), a navigation device, or an Ultra Mobile PC (UMPC), a television (TV), a laptop, a monitor, a billboard, an Internet of Things (IoT) device, and the like. Also, in an embodiment, the display apparatus 1 may be used in a wearable device, such as a smartwatch, a watch phone, an eyewear display, or a head-mounted display (HMD). Also, in an embodiment, the display device 1 may be used as a display in an instrument cluster of a vehicle, a Center Information Display (CID) mounted on a center fascia or a dashboard of a vehicle, a room mirror display replacing a side-view mirror of a vehicle, or a car headrest monitor provided for rear-seat entertainment.

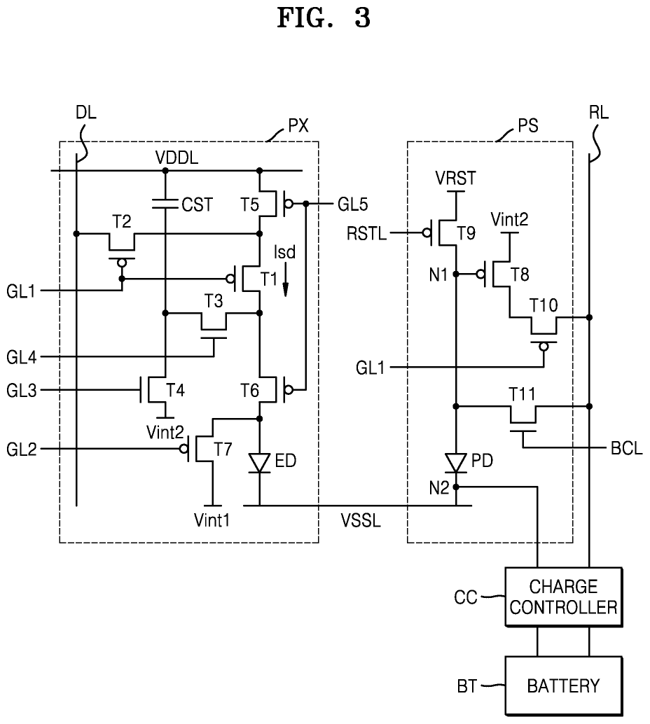

FIG. 3 is a detailed circuit diagram of a pixel and a photo sensor, according to an embodiment.

The pixel PX may include a pixel circuit and a light-emitting diode ED as a display element connected to the pixel circuit. The pixel circuit may include a plurality of transistors and at least one capacitor. The pixel circuit may be connected to a first gate line GL1 to which a first gate signal is applied, a second gate line GL2 to which a second gate signal is applied, a third gate line GL3 to which a third gate signal is applied, a fourth gate line GL4 to which a fourth gate signal is applied, a fifth gate line GL5 to which a fifth gate signal is applied, and a data line DL.

Also, each pixel PX may be connected to a first driving voltage line VDDL to which a first driving voltage is applied, a second driving voltage line VSSL to which a second driving voltage is applied, a first initialization voltage line to which a first initialization voltage Vint1 is applied, and a second initialization voltage line to which a second initialization voltage Vint2 is applied.

Because the emission of the pixel PX is controlled based on the fifth gate signal, the fifth gate signal may be referred to as an emission control signal, and the fifth gate line GL5 may be referred to as an emission control line.

The photo sensor PS may include a sensing circuit and a photodiode PD as a light sensing element connected to the sensing circuit. The sensing circuit may include a plurality of transistors. The sensing circuit may be connected to the readout line RL and a plurality of control lines (CL of FIG. 2). The control lines CL may be connected to a first gate line GL1, a reset line RSTL, and a sixth gate line BCL. Also, the sensing circuit may be connected to the second driving voltage line VSSL to which the second driving voltage is applied, a reset voltage line to which a reset voltage VRST is applied, and the second initialization voltage line to which the second initialization voltage Vint2 is applied.

Each pixel PX may include the transistors, the light-emitting diode ED, and at least capacitor CST. The transistors may include a first transistor T1 to a seventh transistor T7. The first transistor T1 may be a driving transistor, and the second transistor T2 to the seventh transistor T7 may each be a switching transistor functioning as a switch element that is turned on or off according to a gate signal applied to a gate electrode.

The first transistor T1 may include a gate electrode, a first electrode, and a second electrode. The first transistor T1 may control a source-drain current Isd (hereinafter, referred to as a “driving current”) according to a data voltage applied to the gate electrode.

The gate electrode of the first transistor T1 may be connected to a first electrode of the third transistor T3 and an electrode of the capacitor CST, the first electrode may be connected to a second electrode of the second transistor T2 and a second electrode of the fifth transistor T5, and the second electrode may be connected to a second electrode of the third transistor T3 and a first electrode of the sixth transistor T6.

The second transistor T2 may be turned on according to the first gate signal of the first gate line GL1 and connect the first electrode of the first transistor T1 to the data line DL. A gate electrode of the second transistor T2 may be connected to the first gate line G1, a first electrode may be connected to the data line DL, and the second electrode may be connected to the first electrode of the first transistor T1.

The third transistor T3 may be turned on according to the fourth gate signal of the fourth gate line GL4 and connect the gate electrode of the first transistor T1 to the second electrode thereof. That is, when the third transistor T3 is turned on, the first transistor T1 is driven as a diode because the gate electrode of the first transistor T1 is connected to the second electrode thereof, and thus, a threshold voltage of the first transistor T1 may be compensated for. A gate electrode of the third transistor T3 may be connected to the fourth gate line GL4, the first electrode may be connected to the second electrode of the first transistor T1, and the second electrode may be connected to the gate electrode of the first transistor T1.

The fourth transistor T4 may be turned on according to the third gate signal of the third gate line GL3 and connect the gate electrode of the first transistor T1 to the second initialization voltage line. In this case, the gate electrode of the first transistor T1 may be initialized to the second initialization voltage Vint2 of the second initialization voltage line. A gate electrode of the fourth transistor T4 may be connected to the third gate line GL3, a first electrode may be connected to the second initialization voltage line, and a second electrode may be connected to the gate electrode of the first transistor T1.

The fifth transistor T5 may be turned on according to an emission signal of the fifth gate line GL5 and connect the first electrode of the first transistor T1 to the first driving voltage line VDDL. A gate electrode of the fifth transistor T5 may be connected to the fifth gate line GL5, a first electrode may be connected to the first driving voltage line VDDL, and the second electrode may be connected to the first electrode of the first transistor T1.

The sixth transistor T6 may be turned on according to the emission signal of the fifth gate line GL5 and connect the second electrode of the first transistor T1 to an anode of the light-emitting diode ED. A gate electrode of the sixth transistor T6 may be connected to the fifth gate line GL5, the first electrode may be connected to the second electrode of the first transistor T1, and the second electrode may be connected to the anode of the light-emitting diode ED.

When the fifth transistor T5 and the sixth transistor T6 are all turned on, the driving current may be supplied to the light-emitting diode ED.

The seventh transistor T7 may be turned on according to the second gate signal of the second gate line GL2 and connect the first initialization voltage line to the anode of the light-emitting diode ED. In this case, the anode of the light-emitting diode ED may be discharged (initialized) to the first initialization voltage Vint1. A gate electrode of the seventh transistor T7 may be connected to the second gate line GL2, a first electrode may be connected to the first initialization voltage line, and a second electrode may be connected to the anode of the light-emitting diode ED. In an embodiment, the second gate line GL2 may be the first gate line GL1 in a previous row, and the second gate signal may be a first gate signal provided to the previous row.

The capacitor CST may be formed between the gate electrode of the first transistor T1 and the first driving voltage line VDDL. An electrode of the capacitor CST may be connected to the gate electrode of the first transistor T1, and another electrode thereof may be connected to the first driving voltage line VDDL. Thus, the capacitor CST may keep a potential difference between the gate electrode of the first transistor T1 and the first driving voltage line VDDL.

The light-emitting diode ED emits light according to the driving current. The amount of light emitted from the light-emitting diode ED may be proportional to the driving current.

The light-emitting diode ED may be an organic light-emitting diode OLED including an anode, a cathode, and an organic emission layer arranged between the anode and the cathode. Alternatively, the light-emitting diode ED may be an inorganic light-emitting diode including an anode, a cathode, and an inorganic emission layer arranged between the anode and the cathode, or a quantum dot organic light-emitting diode including a quantum dot emission layer arranged between an anode and a cathode. Also, the light-emitting diode ED may be a micro-light-emitting diode.

The anode of the light-emitting diode ED may be connected to the second electrode of the sixth transistor T6 and the second electrode of the seventh transistor T7, and the cathode of the light-emitting diode ED may be connected to the second driving voltage line VSSL.

Each photo sensor PS may include a plurality of sensing transistors and a photodiode PD. The sensing transistors may include a first sensing transistor T8, a second sensing transistor T10, and a third sensing transistor T9. Hereinafter, a node connected to the first sensing transistor T8, the third sensing transistor T9, and the photodiode PD is referred to as a first node N1, and a node connected to the second driving voltage line VSSL and the photodiode PD is referred to as a second node N2. The first sensing transistor T8 may be a driving transistor, and the second sensing transistor T10 and the third sensing transistor T9 may each be a switching transistor functioning as a switch element that is turned on or off according to a signal applied to a gate electrode.

When the light-emitting diode ED and the photodiode PD are disposed above one substrate, a voltage line or a signal line for the operation of the light-emitting diode ED and the photodiode PD may be shared. That is, by reducing additional arrangement of voltage lines or signal lines for the operation of photodiodes PD on a display panel, the resolution of the display panel may be secured, and a bezel area may decrease.

For example, a signal line connected to the gate electrode of the second transistor T2 of the pixel PX may be shared with a signal line connected to a gate electrode of the second sensing transistor T10 of the photo sensor PS. That is, the gate electrode of the second transistor T2 and the gate electrode of the second sensing transistor T10 may be connected to the first gate line GL1.

In some embodiments, the second driving voltage line VSSL may be a common voltage line connected to the cathode of the light-emitting diode ED and the cathode of the photodiode PD.

In some embodiments, the second initialization voltage line, through which the second initialization voltage Vint2 is applied, may be a common voltage line connected to the second electrode of the first sensing transistor T8 of the photo sensor PS and the second electrode of the fourth transistor T4.

The anode of the photodiode PD may be connected to the first node N1 and the cathode thereof may be connected to the second node N2.

When the photodiode PD is exposed to light, photo charges may be generated, and the generated photo charges may be accumulated in the photodiode PD. In this case, a voltage of the first node N1 electrically connected to the anode may increase. Depending on whether the first sensing transistor T8 and the second sensing transistor T10 are turned on, a photocurrent may flow through the readout line RL in proportion to the voltage of the first node N1 in which the photo charges are accumulated.

The gate electrode of the first sensing transistor T8 may be connected to the first node N1, the first electrode may be connected to the second initialization voltage line, and the second electrode may be connected to the first electrode of the second sensing transistor T10. The first sensing transistor T8 may be a source follower amplifier for generating a source-drain current in proportion to the amount of charges in the first node N1 input to the gate electrode. The first sensing transistor T8 may generate a photocurrent flowing to the readout line RL from the second initialization voltage line through the second sensing transistor T10, based on the voltage of the first node N1 determined based on the photo charges accumulated in the photodiode PD. FIG. 3 shows that the first electrode of the first sensing transistor T8 is connected to the second initialization voltage line, but in another embodiment, the first electrode of the first sensing transistor T8 may be connected to the first driving voltage line VDDL or the first initialization voltage line.

The second sensing transistor T10 may be turned on according to the first gate signal of the first gate line GL1 and connect the second electrode of the first sensing transistor T8 to the readout line RL. The gate electrode of the second sensing transistor T10 may be connected to the first gate line GL1, the first electrode may be connected to the second electrode of the first sensing transistor T8, and the second electrode may be connected to the readout line RL.

The third sensing transistor T9 may be turned on according to the reset signal from the reset line RSTL to reset the first node N1 to a reset voltage VRST. The gate electrode of the third sensing transistor T9 may be connected to the reset line RSTL, the first electrode may be connected to a reset voltage line, and the second electrode may be connected to the first node N1. The reset voltage VRST may be a voltage allowing a dark current to flow through the photodiode PD. A fingerprint sensing signal may be detected from a ratio of the photocurrent and the dark current.

A fourth sensing transistor T11 may be turned on according to the sixth gate signal of the sixth gate line BCL and connect the anode of the photodiode PD to the readout line RL. A photocurrent generated based on the intensity of external light incident on the photodiode PD may be input to the charge controller CC through the readout line RL, and the charge controller CC may control a received current to deliver the same to the battery BT, and a voltage may be stored in the battery BT.

When the first electrode of each of the first transistor T1 to the seventh transistor T7 and the first sensing transistor T8 to the fourth sensing transistor T11 is a source electrode, the second electrode thereof may be a drain electrode. Alternatively, when the first electrode of each of the first transistor T1 to the seventh transistor T7 and the first sensing transistor T8 to the fourth sensing transistor T11 is a drain electrode, the second electrode thereof may be a source electrode.

An active layer of each of the first transistor T1 to the seventh transistor T7 and the first sensing transistor T8 to the fourth sensing transistor T11 may include any one of polysilicon, amorphous silicon, and an oxide semiconductor.

For example, the first transistor T1, the second transistor T2, the fifth transistor T5 to the seventh transistor T7, and the first sensing transistor T8 to the third sensing transistor T9 may each be a P-type transistor. In this case, the active layer of each of the first transistor T1, the second transistor T2, the fifth transistor T5 to the seventh transistor T7, and the first sensing transistor T8 to the third sensing transistor T9 may include polysilicon. Also, each of the third transistor T3, the fourth transistor T4, and the fourth sensing transistor T11 may be an N-type transistor that includes an active layer including an oxide semiconductor.

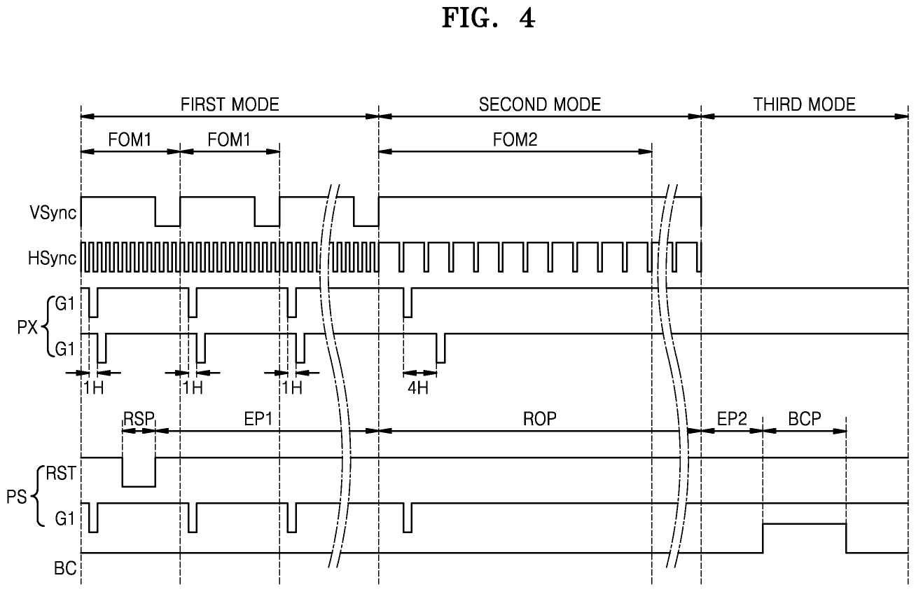

However, one or more embodiments are not limited thereto, and each of the first transistor T1 to the seventh transistor T7 and the first sensing transistor T8 to the fourth sensing transistor T11 may be a P-type transistor. In some embodiments, the first sensing transistor T8 to the fourth sensing transistor T11 may each be an N-type transistor. In this case, the circuit diagram of FIG. 3 and the waveform of FIG. 4 need to be modified based on the characteristics of each transistor.

FIG. 4 shows signals in a first mode to a third mode, according to an embodiment.

The display apparatus 1 may operate in a first mode that is a display mode, a second mode in which a fingerprint is sensed, and a third mode that is a charging mode in which received light is stored. In the first mode, the display apparatus 1 may display images by using light emitted from the pixels PX. In the second mode, when a finger contacts or comes close to the display apparatus 1, the display apparatus 1 may use the photo sensors PS to sense light that is emitted from some of the pixels PX and then reflected from the finger. In the third mode, the display apparatus 1 may store, in a battery BT, electrical energy corresponding to the amount of external light received by the photo sensors PS.

First of all, the first gate signal G1 is a signal applied to the first gate line GL1 and a signal for controlling the turning on and off of the second transistor T2 of the pixel PX and the second sensing transistor T10 of the photo sensor PS. A frame frequency refers to a frequency in which data signals are written to the driving transistor (e.g., the first transistor T1) of the pixel PX and may indicate the number of frames played per second. In each frame, the pixel PX may receive a data signal when the first gate signal G1 is provided to the first gate line GL1. A frame duration may be playback time of one frame.

The pixel PX and the photo sensor PS may operate at a first frame frequency in the first mode and operate at a second frame frequency in the second mode. The first frame frequency may be higher than the second frame frequency. A first frame duration FOM1 in the first mode may be less than a second frame duration FOM2 in the second mode.

The reset signal RST of the photo sensor PS is applied to the reset line RSTL and is a signal for controlling the turning on and off of the third sensing transistor T9. The reset signal RST may be a signal different from the gate signals GS. In other words, by separating the reset signal RST of the photo sensor PS from the gate signals GS of the pixel PX instead of sharing the reset signal RST, the reset timing of the photo sensor PS and the number of times that the photo sensor PS is reset may be independently adjusted. For example, the reset signal RST may be output when a user's touch is generated, and the photo sensor PS may enter a reset period RSP.

When a touch of the user is made, the photo sensor PS may start, in the first mode, a reset period RSP in which the anode of the photodiode PD is reset to the reset voltage VRST and a light exposure period EP in which the photodiode PD is exposed to light, photo charges are generated according to the intensity of external light, and thus, the voltage of the anode of the photodiode PD and the voltage of the first node N1 increase, and may start, in the second mode, a fingerprint reading period ROP in which the second sensing transistor T10 is turned on during the second frame duration FOM2 and a fingerprint is read according to the intensity of the current flowing through the readout line.

The reset signal RST may have a gate-on voltage Von during the reset period RSP and a gate-off voltage Voff during other periods. The gate-on voltage Von of the reset signal RST may be a gate low voltage, and the gate-off voltage Voff thereof may be a gate high voltage.

When a touch of the user is generated while the display apparatus 1 operates in the first mode and displays images, the reset period RSP may start. During the reset period RST, the reset signal RST having the gate-on voltage Von is provided to the reset line RSTL. Thus, the third sensing transistor T9 is turned on, and the first node N1 and the anode of the photodiode PD may be reset to the reset voltage VRST. Due to a second driving voltage VSS being higher than the reset voltage VRST is applied to the cathode of the photodiode PD and the second node N2, the photodiode PD may maintain a reverse bias state. For example, the voltage of the first node N1 may be about −6.5 V, and the voltage of the second node N2 may be about −2.5 V.

Then, during the light exposure period EP, the photodiode PD may be exposed to the light emitted from the light-emitting diode ED. When the touch of the user is generated, the photodiode PD may generate photo charges corresponding to the light reflected from ridges of a fingerprint or valleys between the ridges, and a reverse current may be generated in proportion to the amount of the generated photo charges. That is, a current flowing from the second node N2 to the first node N1 may be generated. Accordingly, the voltage of the first node N1 may increase. The voltage of the first node N1 may increase until the potential difference between the first electrode and the gate electrode of the first sensing transistor T8 reaches an absolute value of a threshold voltage. When the voltage of the first node N1 reaches the threshold voltage of the first sensing transistor T8, the first sensing transistor T8 may be turned on. The light exposure period EP may correspond to a period in which the first frame duration FOM1 proceeds 12 times.

Then, during the fingerprint reading period ROP, the first gate signal G1 having the gate-on voltage Von may be provided to the first gate line GL1. To this end, the second sensing transistor T10 may be turned on, and a fingerprint sensing signal corresponding to a current flowing through the first sensing transistor T8 may be output to the readout line. The current flowing through the first sensing transistor T8 may be a source-drain current generated in proportion to the amount of charges of the first node N1 that are input to the gate electrode of the first sensing transistor T8. Therefore, ridges or valleys of the fingerprint may be determined by sensing the voltage change in the first node N1, and the fingerprint may be detected.

Hereinafter, the operation of the pixel PX and the photo sensor PS according to the first mode to the third mode is described. FIG. 4 shows the first gate signal G1, the reset signal RST, and the sixth gate signal G6 which are provided to the pixel PX and the photo sensor PS, and other signals are omitted.

A frame frequency refers to a frequency in which data signals are substantially input to the driving transistor (e.g., the first transistor T1) of the pixel PX and may indicate the number of frames played per second. In each frame, the pixel PX may receive a data signal when the first gate signal G1 is provided to the first gate line GL1. A frame duration may be playback time of one frame. A first frame duration FOM1 in the first mode may be less than a second frame duration FOM2 in the second mode.

The pixel PX and the photo sensor PS may operate at the first frame frequency in the first mode and operate at the second frame frequency in the second mode. The first frame frequency may be higher than the second frame frequency.

When the touch of the user is sensed in the first mode, the photo sensor PS may operate at the first frame frequency during a period corresponding to the preset reset period RSP and the light exposure period EP, and when the second mode starts in synchronization with a point in time when the fingerprint reading period ROP starts, the photo sensor PS may operate at the second frame frequency. For example, the preset reset period may be about 100 ms and correspond to about 12 first frame durations FOM1, but one or more embodiments are not limited thereto. When the second mode ends, the pixel PX and the photo sensor PS may switch back to the first mode and operate at the first frame frequency. After the first mode and the second mode end, the pixel PX and the photo sensor PS may switch to the third mode, and the charging mode may start.

In the first mode, the pixel PX may receive a vertical synchronization signal Vsync and a horizontal synchronization signal Hsync, both having the first frame frequency. The pixel PX and the photo sensor PS may repeat the first frame duration FOM1 and operate according to the vertical synchronization signal Vsync and the horizontal synchronization signal Hsync having the first frame frequency.

In the first mode, the display apparatus 1 may display an image at the first frame frequency. Because the reset signal RST is not output in the first mode, a fingerprint sensing signal may not be accurately sensed even though the first gate signal G1 is applied to the photo sensor PS. For example, because no reset voltage is applied to the first node N1, the reverse bias of the photodiode PD may not be generated, and the photocurrent may not be generated despite the exposure of the photodiode PD to external light. In some embodiments, even when the reset signal RST is output, the readout circuit ROC may not take a signal generated during the first frame duration FOM1 as valid fingerprint sensing data. In the second mode in which a fingerprint is sensed, the photo sensor PS may receive a vertical synchronization signal Vsync and a horizontal synchronization signal Hsync, both having the second frame frequency. During the second frame duration FOM2, the photo sensor PS may operate the vertical synchronization signal Vsync and the horizontal synchronization signal Hsync which have the second frame frequency.

In the second mode, the display apparatus 1 may display an image at the second frame frequency. Also, the display apparatus 1 may sense a fingerprint according to the user's touch.

In the third mode, the pixel PX may not be driven, and the first gate signal G1 for driving the pixel PX may not be input. In the third mode, because the reset signal RST and the first gate signal G1 are not applied, no images may be displayed, and an external object (a fingerprint) may not be sensed. Therefore, the vertical synchronization signal Vsync and the horizontal synchronization signal Hsync may not be applied as well.

In the third mode, because the sixth gate signal G6 is applied, the light received by the photodiode PD may be input to the charge controller CC along the readout line in the form of photocurrent.

Referring to FIG. 4, the display apparatus 1 may start operating in the third mode when neither an image signal nor a fingerprint sensing signal is detected, and the sixth gate signal G6 may have the gate-on voltage. If the display apparatus 1 operates in at least one of the first mode and the second mode, the third mode is terminated, and the sixth gate signal G6 may have the gate-off voltage. As shown in FIG. 4, for example, if the controller CTR receives image data while the display apparatus 1 operates in the third mode, the display apparatus 1 may terminate the third mode and operate in the first mode to display images. Similarly, if a touch input is sensed, the display apparatus 1 may operate in the second mode as the reset period RSP and the light exposure period EP may proceed.

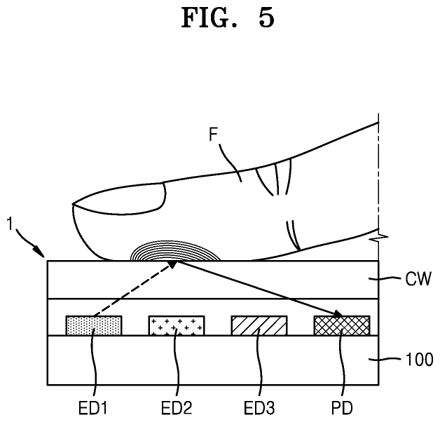

FIG. 5 is a schematic cross-sectional view showing a principle of detecting a fingerprint as a display apparatus operates in a second mode, according to an embodiment.

Referring to FIG. 5, the display apparatus 1 according to an embodiment may include the substrate 100, and light-emitting diodes ED and photodiodes PD disposed above the substrate 100. The light-emitting diodes ED may include a first light-emitting diode ED1, a second light-emitting diode ED2, and a third light-emitting diode ED3. The first light-emitting diode ED1, the second light-emitting diode ED2, and the third light-emitting diode ED3 may emit different light. For example, the first light-emitting diode ED1 may emit green light, the second light-emitting diode ED2 may emit red light, and the third light-emitting diode ED3 may emit blue light.

As shown in FIG. 5, the display apparatus 1 may have a function of sensing a target (an external object), e.g., a fingerprint of a finger F, that is in contact with a cover window CW. Light that originates from at least one of the first light-emitting diode ED1, the second light-emitting diode ED2, and the third light-emitting diode ED3 may be reflected off the finger F back toward the substrate 100, the reflected light may be incident on the photodiode PD. The photodiode PD may detect the reflected light. For example, as green light emitted from the first light-emitting diode ED1 is reflected off an object contacting the cover window CW and incident on the photodiode PD, the photodiode PD may detect the green light.

The operation of detecting a fingerprint by the photo sensor PS of the display apparatus 1 of FIG. 5 may be performed in the second mode according to an embodiment.

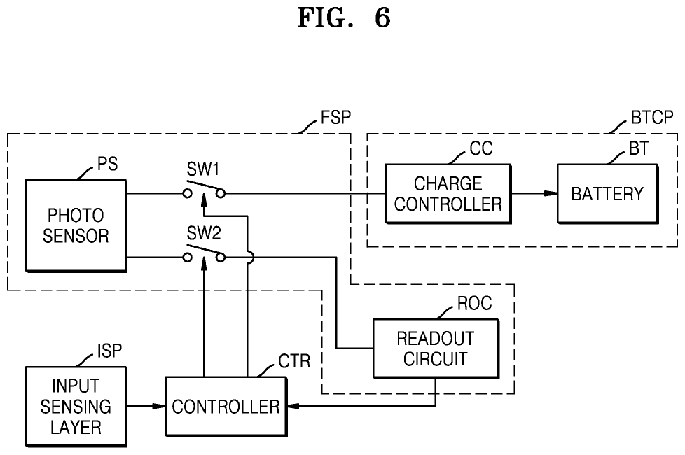

FIG. 6 schematically shows components of the display apparatus 1 according to an embodiment.

Referring to FIG. 6, the display apparatus may include a fingerprint sensing portion FSP and a battery charging portion BTCP. The fingerprint sensing portion FSP may include the photo sensor PS and the readout circuit ROC. In an embodiment, the fingerprint sensing portion FSP may further include a first switch FW1 and a second switch SW2. The first switch SW1 may be connected to the photo sensor PS and the charge controller CC. The second switch SW2 may be connected to the photo sensor PS and the readout circuit ROC.

Also, as the display apparatus 1 operates in the third mode, the photo sensor PS may be connected to the battery BT. In detail, the photo sensor PS may be connected to the charge controller CC through the first switch SW1. The photo sensor PS may be connected to the battery BT through the charge controller CC. However, one or more embodiments are not limited thereto, and the photo sensor PS may be directly connected to the charge controller CC without the first switch SW1.

The photo sensor PS may be connected to the readout circuit ROC through the second switch SW2.

The battery charging portion BTCP may be disposed above the display circuit board (30 of FIG. 1). The battery charging portion BTCP may include the charge controller CC and the battery BT, and the battery BT may be connected to the charge controller CC.

The readout circuit ROC may be arranged in the peripheral area (PA of FIG. 1) and connected to at least one readout line RL arranged in the display area (DA of FIG. 1). The photo sensor PS may be connected to the charge controller CC through at least one readout line RL.

The charge controller CC may include a capacitive element (a capacitor). The current flowing through the readout line RL may be converted into a voltage in the charge controller CC and stored in the capacitive element.

The readout circuit ROC may be connected to the controller CTR, and the controller CTR may be connected to an input sensing layer ISP. The controller CTR may control switching operations of the first switch SW1 and the second switch SW2. For example, the controller CTR may turn on or off the first switch SW1 and the second switch SW2.

For example, the first switch SW1 and the second switch SW2 may each be a transistor. In this case, the controller CTR may provide control signals to gates of the first switch SW1 and the second switch SW2.

The readout circuit ROC may receive, as fingerprint information, an optical signal sensed by the photo sensor PS. The readout circuit ROC may process the optical signal sensed by the photo sensor PS into the fingerprint information and provide processed information to the controller CTR.

When the display apparatus 1 operates in the second mode, and when a touch from an external object is detected in the input sensing layer ISP, the controller CTR may control the operation of the second switch SW2 such that the second switch SW2 may be turned on. When the second switch SW2 is turned on, the photo sensor PS may sense the light reflected from the fingerprint of the external object (the finger), the photocurrent may be transmitted to the readout circuit ROC through the readout line RL, and the readout circuit ROC may process a light sensing signal received from the photo sensors PS according to the readout control signal RCS from the controller CTR and provide a processed signal ROS to the controller CTR.

When the display apparatus 1 operates in the third mode, there may be no image signal or fingerprint sensing signal. In the absence of image signal and fingerprint sensing signal, the first switch SW1 may be turned on by default according to a control signal transmitted from the controller CTR, and the photo sensor PS and the charge controller CC are connected to each other; thus, the photocurrent flowing through the readout line RL in the display area DA may be transmitted to the charge controller CC. The transmitted photocurrent may be controlled in the charge controller CC and transmitted to the battery BT, and as the voltage is stored in the battery BT, the display apparatus 1 may perform a charging function.

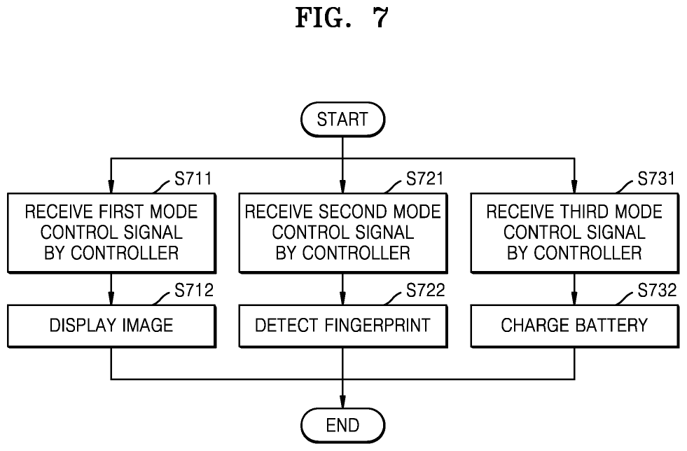

FIG. 7 is a flowchart of operations in a first mode, a second mode, and a third mode, according to an embodiment.

With regard to the operation in the first mode, when the controller CTR receives a first mode control signal in operation S711, a display panel may display an image in the first mode in operation S712.

With regard to the operation in the second mode, when the controller CTR receives a second mode control signal in operation S721, a display panel may display an image in the second mode in operation S712. The readout circuit ROC may accurately detect a fingerprint based on a readout control signal RCS from the controller CTR.

With regard to the operation in the third mode, when the controller CTR receives a third mode control signal in operation S731, a voltage may be stored in the battery BT in the third mode, and the display apparatus 1 may perform the charging function in operation S732. That is, when the display apparatus 1 does not operate in the first mode and the second mode, the photocurrent flowing between the anode and the cathode of the photodiode PD may be transmitted to the charge controller CC by applying the sixth gate signal G6 to the fourth sensing transistor T11. The current may be converted into a voltage in the charge controller CC, and a converted voltage may be applied to the battery BT. During this process, the voltage may be increased and stored in the battery BT, with the photo sensor functioning as a battery. This photo sensor charging process happens in the third mode. Only one of the first mode, the second mode, and the third mode may be active at a given time.

FIG. 8 is a diagram showing an arrangement structure of pixels and photo sensors, according to an embodiment.

FIG. 8 shows a photo sensor PS including a pixel electrode PE, an emission area, and a photodiode of each of a first pixel PX1, a second pixel PX2, and a third pixel PX3. The emission area is where an emission layer of the light-emitting diode is arranged. Each pixel electrode PE may include a first area PEA1 corresponding to the emission area and a second area PEA2 surrounding the first area PEA1.

As illustrated in FIG. 8, the emission areas are arranged in first columns M1 and second columns M2 that alternate, and first sub-rows SN1 and second sub-rows SN2 that alternate. In first columns M1, first emission areas EA1 of the first pixels PX1 and third emission areas EA3 of the third pixels PX3 may be alternately arranged in a y direction. The pixels PX1 and PX3 are arranged in the first sub-rows SN1. The second sub-rows SN2 between the first pixel PX1 and the third pixel PX3, and photodiodes PD of the photo sensors PS are arranged in the second sub-rows SN2 and first columns M1. In second columns M2, second emission areas EA2 of the second pixels PX2 may be repeatedly arranged in the y direction. Among the first columns M1, the first columns M1 may alternate between ones that have the first emission areas EA1 of the first pixels PX1 in the first sub-rows SN1 and ones that have the third emission areas EA3 of the third pixels PX3 in the first sub-rows SN1. Thus, just looking at the first columns M1, the first pixels PX1 and the third pixels PX3 alternate in a first sub-row SN1.

In a first sub-row SN1 of each row N, the first emission area EA1 of the first pixel PX1 and the third emission area EA3 of the third pixel PX3 may be alternately arranged in the x direction, and in the second sub-row SN2, the second emission area EA2 of the second pixel PX2 and the area where the photodiode PD of the photo sensor PS is arranged in the first column M1 between the second pixels PX2 may be alternately arranged in the x direction. That is, in each row N, the first emission area EA1 of the first pixel PX1, the second emission area EA2 of the second pixel PX2, the third emission area EA3 of the third pixel PX3, and the photodiode PD of the photo sensor PS may be arranged in a diamond shape and repeated in a zigzag form.

The first emission area EA1 of the first pixel PX1, the second emission area EA2 of the second pixel PX2, and the third emission area EA3 of the third pixel PX3 may have different dimensions. In an embodiment, the third emission area EA3 of the third pixel PX3 may have a greater area than the first emission area EA1 of the first pixel PX1. Also, the third emission area EA3 of the third pixel PX3 may have a greater area than the second emission area EA2 of the second pixel PX2. The first emission area EA1 of the first pixel PX1 may have a greater area than the second emission area EA2 of the second pixel PX2. In some embodiments, the third emission area EA3 of the third pixel PX3 may have the same area as the first emission area EA1 of the first pixel PX1. However, one or more embodiments are not limited thereto. Various modifications may be made. For example, the first emission area EA1 of the first pixel PX1 may have a greater area than the second emission area EA2 of the second pixel PX2 and the third emission area EA3 of the third pixel PX3.

The first emission area EA1, the second emission area EA2, and the third emission area EA3 may each have a polygonal shape such as a rectangle or an octagon, or a circle or an oval The polygonal shape may be a polygon with rounded corners (edges).

In an embodiment, the first pixel PX1 may be a red pixel R emitting red light, the second pixel PX2 may be a green pixel G emitting green light, and the third pixel PX3 may be a blue pixel B emitting blue light.

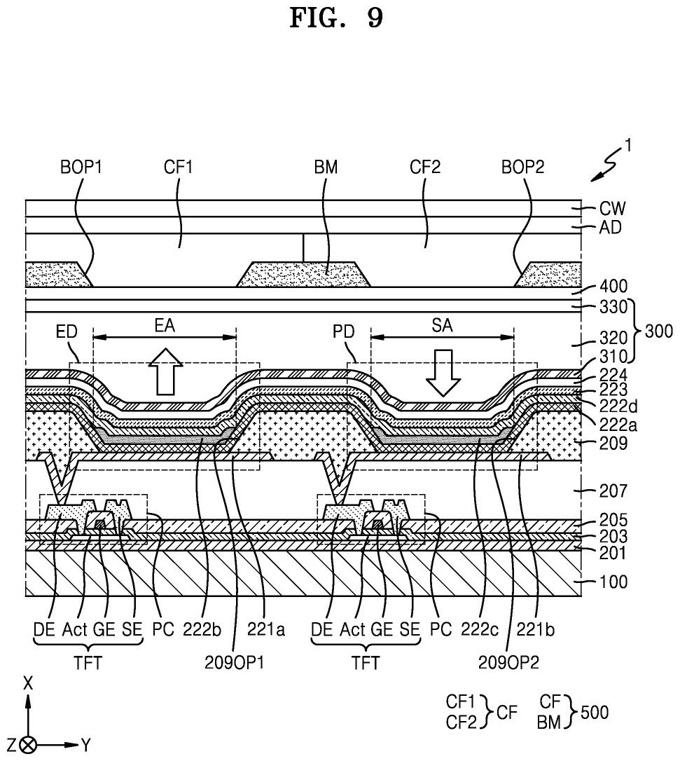

The structure 9 in which one pixel PX and one photo sensor PS of FIG. 8 are taken along in x, y, and x directions is described below with reference to FIG. 9.

FIG. 9 is a schematic cross-sectional view of a portion of a display apparatus, according to an embodiment. FIG. 9 may be a cross-sectional view showing a portion of the display area DA of the display apparatus of FIG. 1.

Referring to FIG. 9, the display apparatus 1 may include a substrate 100 and a pixel and a photo sensor disposed above the substrate 100. The pixel PX may include a pixel circuit and a light-emitting diode ED connected to the pixel circuit. The photo sensor PS may include a sensing circuit and a photodiode PD connected to the sensing circuit. The pixel circuit and the sensing circuit may each include a plurality of thin-film transistors TFT.

The display apparatus 1 may further include an auxiliary layer 224, an encapsulation layer 300, an input sensing layer 400, an anti-reflection layer 500, and a cover window CW disposed above the pixel PX and the photo sensor PS.

The substrate 100 may include glass or polymer resin. For example, when the substrate 100 includes polymer resin, the substrate 100 may include any one of polyimide, polyethyelenene napthalate, polyethylene terephthalate, polyarylate, polycarbonate, polyetherimide, and polyethersulfone.

A buffer layer 201 may be disposed above the substrate 100. The buffer layer 201 may decrease or prevent the penetration of foreign impurities, moisture, or external air from the bottom of the substrate 100. The buffer layer 201 may include an inorganic material, such as silicon oxide, silicon oxynitride, or silicon nitride, and may be a layer or layers including the above material.

The thin-film transistor TFT may be disposed above the buffer layer 201. The thin-film transistor TFT may include a semiconductor layer Act, a gate electrode GE, a source electrode SE, and a drain electrode DE. FIG. 9 shows a top-gate type thin-film transistor TFT in which the gate electrode GE is disposed above the semiconductor layer Act with a gate insulating layer 203 therebetween, but one or more embodiments are not limited thereto. For example, the thin-film transistor TFT may be of a bottom-gate type.

The semiconductor layer Act may be disposed above the buffer layer 201. The semiconductor layer Act may include a channel area and a source area and a drain area arranged on both sides of the channel area and doped with impurities. In this case, the impurities may include N-type impurities or P-type impurities. The semiconductor layer Act may include amorphous silicon or polysilicon. In an embodiment, the semiconductor layer Act may include oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (AI), cesium (Cs), cerium (Ce), and zinc (Zn). The oxide semiconductor Act may include a Zn-oxide-based material and include Zn oxide, In—Zn oxide, Ga—In—Zn oxide, and the like. Also, the semiconductor layer Act may be an In—Ga—Zn—O (IGZO) semiconductor, an In—Sn—Zn—O (ITZO) semiconductor, or an In—Ga—Sn—Zn—O (IGTZO) semiconductor in which metal such as In, Ga, or Sn is included in ZnO.

The gate electrode GE may be disposed above the semiconductor layer Act to at least partially overlap the same. In detail, the gate electrode GE may overlap the channel area of the semiconductor layer Act. Such a gate electrode GE may include various conductive materials including Mo, Al, Cu, and Ti and have various layer structures. For example, the gate electrode GE may include an Mo layer and an Al layer or have a multilayered structure including an Mo layer/an Al layer/an Mo layer. Also, the gate electrode GE may have a multilayered structure including an ITO layer covering a metal material.

The gate insulating layer 203 arranged between the semiconductor layer Act and the gate electrode GE may include an inorganic insulating material, such as silicon oxide, silicon nitride, silicon oxynitride, aluminum oxide, titanium oxide, tantalum oxide, or hafnium oxide. The gate insulating layer 203 may be a layer or layers including the above material.

The source electrode SE and the drain electrode DE may contact a source area and a drain area of the semiconductor layer Act through contact holes. The source electrode SE and the drain electrode DE may each include various conductive materials including Mo, Al, Cu, and Ti and have various layer structures. For example, the source electrode SE and the drain electrode DE may include a Ti layer and an Al layer or have a multilayered structure including a Ti layer/an Al layer/a Ti layer. Also, the source electrode SE and the drain electrode DE may have a multilayered structure including an ITO layer covering a metal material.

An interlayer insulating layer 205 may include an inorganic insulating material, such as silicon oxide, silicon nitride, silicon oxynitride, aluminum oxide, titanium oxide, tantalum oxide, or hafnium oxide. The interlayer insulating layer 205 may be a layer or layers including the above material.

The gate insulating layer 203 and the interlayer insulating layer 205 including the inorganic material may be formed through chemical vapor deposition (CVD) or atomic layer deposition (ALD), but one or more embodiments are not limited thereto.

The thin-film transistor TFT may be covered by an organic insulating layer 207. For example, the organic insulating layer 207 may cover the source electrode SE and the drain electrode DE. The organic insulating layer 207 may be a planarization insulating layer and have an upper surface that is substantially flat. Such an organic insulating layer 207 may include organic insulating materials such as a general-purpose polymer such as polymethylmethacrylate (PMMA) or polystyrene (PS), a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, and any blend thereof. In an embodiment, the organic insulating layer 207 may include polyimide.

A pixel electrode 221a, a sensing electrode 221b, and a bank layer 209 may be disposed above the organic insulating layer 207. The bank layer 209 may cover edges of the pixel electrode 221a and the sensing electrode 221b and be disposed above the organic insulating layer 207.

In the bank layer 209, a first bank layer opening 2090P1 exposing at least a central portion of the pixel electrode 221a and a second bank layer opening 2090P2 exposing at least a central portion of the sensing electrode 221b may be arranged. Thus, the first bank layer opening 2090P1 may define the emission area EA, and the second bank layer opening 2090P2 may define the sensing area SA.

The bank layer 209 prevents arcs, etc. from being generated at the edges of the pixel electrode 221a by increasing a distance between the edges of the pixel electrode 221 a and an opposite electrode 223. Also, the bank layer 209 prevents arcs, etc. from being generated at the edges of the sensing electrode 221b by increasing a distance between the edges of the sensing electrode 221b and the opposite electrode 223.

The bank layer 209 may include an organic insulating material, such as polyimide, polyamide, acrylic resin, benzocyclobutene (BCB), hexamethyldisiloxane (HMDSO), or phenol resin, and may be formed through spin coating or the like.

The emission layer 222b may be arranged in the first bank layer opening 2090P1 formed in the bank layer 209. The emission layer 222b may include an organic material including a fluorescent or phosphorescent material emitting red light, green light, blue light, or white light. The emission layer 222b may be an organic emission layer including a low-molecular-weight organic material or a high-molecular-weight organic material. For example, the emission layer 222b may be an organic emission layer and include copper phthalocyanine, tris-8-hydroxyquinoline aluminum, a poly-phenylenevinylene (PPV)-based material, or a polyfluorene-based material.

In an embodiment, the emission layer 222b may include a host material and a dopant material. The dopant material may be a material emitting a certain color of light and include an emission material. The emission material may include at least one of a phosphorescent dopant, a fluorescent dopant, and a quantum dot. The host material is a main ingredient of the emission layer 222b and helps the dopant material emit light.

The active layer 222c may be arranged in the second bank layer opening 2090P2 formed in the bank layer 209. The active layer 222c may include a p-type organic semiconductor and an n-type organic semiconductor. In this case, the p-type organic semiconductor may function as an electron donor, and the n-type organic semiconductor may function as an electron acceptor.

In an embodiment, the active layer 222c may include a mixed layer in which a p-type organic semiconductor is mixed with an n-type organic semiconductor. In this case, the active layer 222c may be formed by co-depositing a p-type organic semiconductor and an n-type organic semiconductor. When the active layer 222c is a mixed layer, excitons may be generated within a diffusion length from a donor-acceptor interface.

In an embodiment, the p-type organic semiconductor may be a compound that functions as an electron donor donating electrons. For example, the p-type organic semiconductor may include boron subphthalocyanine chloride (SubPc), copper II phthalocyanine (CuPu), tetraphenyl-dibenzoperiflanthene (DBP), or an arbitrary combination thereof, but one or more embodiments are not limited thereto.

In an embodiment, the n-type organic semiconductor may be a compound that functions as an electron acceptor accepting electrons. For example, the n-type organic semiconductor may include C60 fullerene, C70 fullerene, or an arbitrary combination thereof, but one or more embodiments are not limited thereto.

In an embodiment, the opposite electrode 223 may be disposed above the emission layer 222b and the active layer 222c. The opposite electrode 223 disposed above the emission layer 222b and the active layer 222c may be integrally formed as a single body. A portion of the opposite electrode 223 disposed above the active layer 222c may be referred to as a sensing opposite electrode. The opposite electrode 223 may be a light-transmissive electrode or a reflection electrode. In some embodiments, the opposite electrode 223 may be a transparent or translucent electrode and may include a metal thin-film having a low work function and including Li, Ca, LiF/Ca, LiF/AI, Al, Ag, Mg, and a compound thereof. Also, the opposite electrode 223 may further include a transparent conductive oxide (TCO) layer including ITO, IZO, ZnO, or In₂O₃ in addition to the metal thin-film.

In an embodiment, a first common layer 222a may be arranged between the pixel electrode 221a and the emission layer 222b and between the sensing electrode 221b and the active layer 222c, and a second common layer 222d may be arranged between the emission layer 222b and the opposite electrode 223 and between the active layer 222c and the opposite electrode 223.

In an embodiment, a hole transport region may be defined between the pixel electrode 221a and the emission layer 222b and between the sensing electrode 221b and the active layer 222c, and an electron transport region may be defined between the emission layer 222b and the opposite electrode 223 and between the active layer 222c and the opposite electrode 223.

The hole transport region may have a single-layer structure or a multilayered structure. For example, the first common layer 222a may be arranged in the hole transport region. In an embodiment, the first common layer 222a may include at least one of a hole injection layer (HIL), a hole transport layer (HTL), and an electron blocking layer (EBL).

For example, the first common layer 222a may have a single-layer structure or a multilayered structure. When the first common layer 222a includes a multilayered structure, the first common layer 222a may include the HIL and the HTL sequentially stacked from the pixel electrode 221a, both the HIL and the EBL, both the HTL and the EBL, or the HIL, the HTL, and the EBL. However, one or more embodiments are not limited thereto.

The first common layer 222a may include at least one selected from among m-MTDATA, TDATA, 2-TNATA, NPB(NPD), p-NPB, TPD, Spiro-TPD, Spiro-NPB, methylated-NPB, TAPC, HMTPD, TCTA(4,4′,4″-tris(N-carbazolyl)triphenylamine, Polyaniline/Dodecylbenzenesulfonic acid (Pani/DBSA), Polyaniline/Camphor sulfonic acid (Pani/CSA), Poly(3,4-ethylenedioxythiophene)/Poly(4-styrenesulfonate (PEDOT/PSS), and Polyaniline/Poly(4-styrenesulfonate (PANI/PSS).

The electron transport region may have a single-layer structure or a multilayered structure. For example, the second common layer 222d may be arranged in the electron transport region. In an embodiment, the second common layer 222d may include at least one of an electron injection layer (EIL), an electron transport layer (ETL), and a hole blocking layer (HBL).

For example, the second common layer 222d may have a single-layer structure or a multilayered structure. When the second common layer 222d has a multilayered structure, the second common layer 222d may include the ETL and the EIL sequentially stacked from the emission layer 222b, both the HBL and the EIL, both the HBL and the ETL, or the HBL, the ETL, and the EIL. However, one or more embodiments are not limited thereto.

The second common layer 222d may include at least one compound selected from among 2,9-Dimethyl-4,7-diphenyl-1,10-phenanthroline (BCP), 4,7-Diphenyl-1,10-phenanthroline (Bphen), Alq3, BAIq, 3-(Biphenyl-4-yl)-5-(4-tert-butylphenyl)-4-phenyl-4H-1,2,4-triazole (TAZ), and NTAZ.

The light-emitting diode ED may include the pixel electrode 221a, the first common layer 222a, the emission layer 222b, the second common layer 222d, and the opposite electrode 223 which are sequentially stacked. The photodiode PD may include the sensing electrode 221b, the first common layer 222a, the active layer 222c, the second common layer 222d, and the opposite electrode 223 (the sensing opposite electrode) which are sequentially stacked.

The thin-film transistor TFT may be arranged between the substrate 100 and the light-emitting diode ED. The thin-film transistor TFT may be electrically connected to the light-emitting diode ED and drive the same. For example, one of the source electrode SE and the drain electrode DE of the thin-film transistor TFT may be electrically connected to the pixel electrode 221a of the light-emitting diode ED.

The thin-film transistor TFT may be arranged between the substrate 100 and the photodiode PD. The thin-film transistor TFT may be electrically connected to the photodiode PD and drive the same. For example, one of the source electrode SE and the drain electrode DE of the thin-film transistor TFT may be electrically connected to the sensing electrode 221b of the photodiode PD.

The photodiode PD may be a light-receiving diode including an anode, a cathode, and a photoelectric conversion layer arranged between the anode and the cathode. The photodiode PD may convert external incident light into an electrical signal. The photodiode PD may be a light-receiving diode or a photo transistor including a pn-type or pin-type inorganic material. Alternatively, the photodiode PD may be an organic light-receiving diode that includes an electron donor material generating donor ions and an electron acceptor material generating acceptor ions. In this case, the donor material and the acceptor material may be compounds described hereinafter.

Donor material: a compound represented by Formula 1.

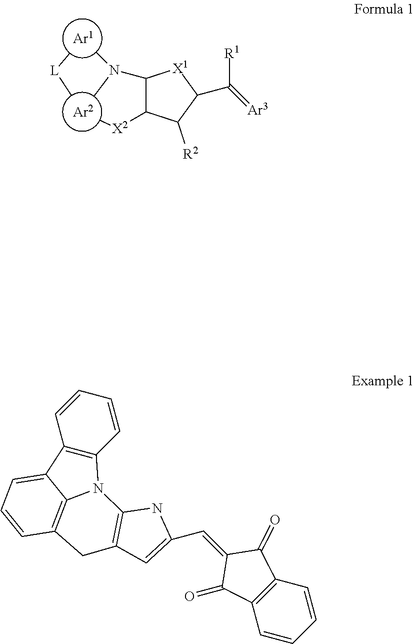

Ar¹ and Ar²: independently a substituted or unsubstituted C6 to C30 arene group, a substituted or unsubstituted C3 to C30 heteroarene group, or a condensed ring thereof, respectively.

X1: selected from among —Se—, —Te—, —S(═O)—, —S(═O)₂—, —NR^{a1}—, —BR^{a2}—, —SiR^{b}R^{c}—, —SiR^{bb}R^{cc}—, —GeR^{d}R^{e}—, —GeR^{dd}R^{ee}—, —CR^{f}R^{g}—, and —CR^{ff}R^{gg}— (wherein R^{a1}, R^{a2}, R^{b}, R^{c}, R^{d}, R^{e}, R_{f}, and R^{g} each are independently hydrogen, deuterium, halogen, a substituted or unsubstituted C1 to C20 alkyl group, a substituted or unsubstituted C1 to C20 alkoxy group, a substituted or unsubstituted C6 to C20 aryl group, or a substituted or unsubstituted C6 to C20 aryloxy group, and at least one pair of R^{bb} and R^{cc}, R^{dd} and R^{ee}, and R^{ff} and R^{gg} is linked together to form a ring structure).

X2: selected from among —O—, —S—, —Se—, —Te—, —S(═O)—, —S(═O)₂—, —NR^{a1}—, —BR^{a2}—, SiR^{b}R^{c}—, —SiR^{bb}R^{cc}—, —GeR^{d}R^{e}—, —GeR^{dd}R^{ee}—, —(CR^{f}R^{g})ₙ₁—, —(CR^{ff}R^{gg})—, —(C(R^{m})═C(Rⁿ))—, —(C(R^{mm})═C(Rⁿⁿ))—, and —(C(R^{p})═N))— (wherein R^{a1}, R^{a2}, R^{b}, R^{c}, R^{d}, R^{e}, R^{f}, R^{g}, R^{m}, Rⁿ and R^{p} each are independently hydrogen, deuterium, halogen, a substituted or unsubstituted C1 to C20 alkyl group, a substituted or unsubstituted C1 to C20 alkoxy group, a substituted or unsubstituted C6 to C20 aryl group, or a substituted or unsubstituted C6 to C20 aryloxy group, and at least one pair of R^{bb} and R^{cc}, R^{dd} and R^{ee}, R^{ff} and R^{gg} and R^{mm} and Rⁿⁿ is linked together to form a ring structure, and n1 in —(CR^{f}R^{g})ₙ₁— is 1 or 2).

L: selected from among —O—, —S—, —Se—, —Te—, —NR^{a1}—, —BR^{a2}—, —SiR^{bb}R^{cc}—, —SiR^{bb}R^{cc}—, —GeR^{d}R^{e}—, —GeR^{dd}R^{ee}—, —(CR^{f}R^{g})ₙ₁—, —(CR^{ff}R^{gg})—, —(C(R^{m})═C(Rⁿ))—, —(C(R^{mm})═C(Rⁿⁿ))—, —(C(R^{p})═N))—, and a single bond (wherein R^{a1}, R^{a2}, R^{b}, R^{c}, R^{d}, R^{e}, R^{f}, R^{g}, R^{m}, Rⁿ and R^{p} each are independently selected from among hydrogen, deuterium, halogen, a substituted or unsubstituted C1 to C20 alkyl group, a substituted or unsubstituted C1 to C20 alkoxy group, a substituted or unsubstituted C6 to C20 aryl group, and a substituted or unsubstituted C6 to C20 aryloxy group, and at least one pair of R^{bb} and R^{cc}, R^{dd} and R^{ee} or R^{ff}, and R^{gg} or R^{mm} and Rⁿⁿ is linked together to form a ring structure, and n1 in —(CR^{f}R^{g})ₙ₁— is 1 or 2).

When L is —NR^{a1}—, —BR^{a2}—, —SiR^{b}R^{c}—, —GeR^{d}R^{e}—, —(CR^{f}R^{g})ₙ₁—, —(C(R^{m})═C(Rⁿ))—, or —(C(R^{p})=N))—, L may be selectively connected to Ar¹ or Ar² to form a ring structure.

R¹ and R² each are independently selected from hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heteroaryl group, a substituted or unsubstituted C2 to C30 acyl group, halogen, a cyano group (—CN), a cyano containing group, a nitro group, a pentafluorosulfanyl group (—SF5), a hydroxyl group, amine group, a hydrazine group, a hydrazone group, a carboxyl group or salt thereof, a sulfonic acid group or salt thereof, a phosphoric acid group or salt thereof, —SiR^{a}R^{b}R^{c} (wherein Rₐ, R^{b}, and R^{c} each are independently selected from among hydrogen and a substituted or unsubstituted C1 to C10 alkyl group), and combinations thereof.

Ar³ is a substituted or unsubstituted C6 to C30 hydrocarbon ring having at least one functional group selected from among C═O, C═S, C═Se, and C═Te, a substituted or unsubstituted C2 to C30 heterocyclic group having at least one functional group selected from among C═O, C═S, C═Se, and C═Te, or a fused ring thereof.

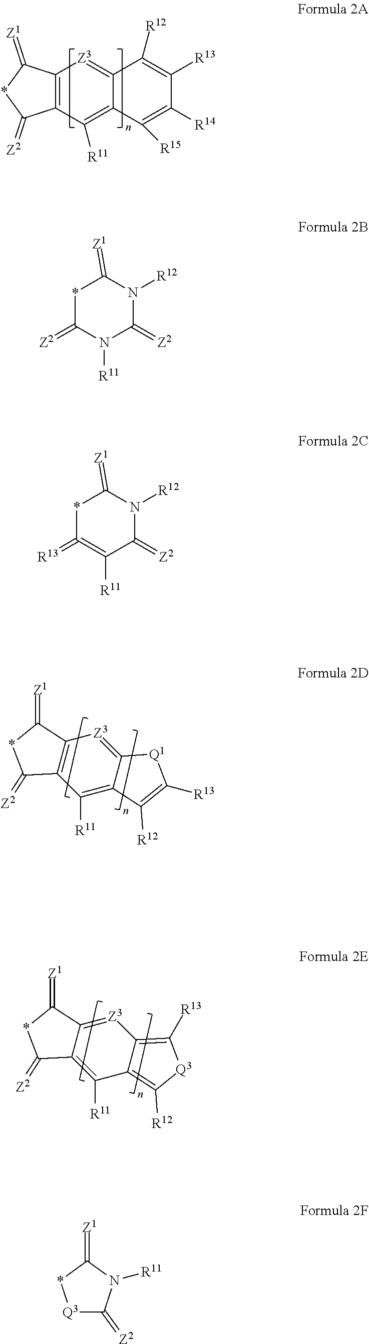

In Formula 1, Ar³ may be a ring represented by any of Formula 2A to Formula 2F.

In Formula above, Z¹ is selected from among O, S, Se, and Te, and Z² is selected from among O, S, Se, Te, and CR^{a}R^{b}, wherein R^{a} and R^{b} each are independently hydrogen, a substituted or unsubstituted C1 to C10 alkyl group, a cyano group, or a cyano-containing group, and when Z² is CR^{a}R^{b}, at least one of R^{a} and R^{b} is a cyano group or a cyano-containing group,

Z³ is selected from among N and CR^{c} (where R^{c} is selected from among hydrogen, deuterium, and a substituted or unsubstituted C1 to C10 alkyl group),

R¹¹, R¹², R¹³, R¹⁴ and R¹⁵ are the same or different and each independently selected from among hydrogen, deuterium, a substituted or unsubstituted C1 to C30 alkyl group, a substituted or unsubstituted C6 to C30 aryl group, a substituted or unsubstituted C4 to C30 heteroaryl group, halogen, a cyano group (—CN), a cyano-containing group, and a combination thereof, or R¹² and R¹³ and R¹⁴ and R¹⁵ may each exist independently or may be linked together to form a fused aromatic ring, wherein n is 0 or 1, and * indicates a bond position. In an embodiment, in Formula above, at least one of CR¹¹, CR¹², CR¹³, CR¹⁴, and CR¹⁵ may be replaced with nitrogen (N). That is, a substituted or unsubstituted benzene ring moiety may contain a heteroatom (N).

G¹, G², and G³ are selected from among O, S, Se, Te, SiR^{x}R^{y}, and GeR^{z}R^{w}, wherein R^{x}, R^{y}, R^{z}, and R^{w} are the same or different and each independently selected from among hydrogen, deuterium, halogen, a substituted or unsubstituted C1 to C20 alkyl group, and a substituted or unsubstituted C6 to C20 aryl group.

Acceptor material: a compound represented by Formula 4A, or one of Formula 5A and Formula 5B.

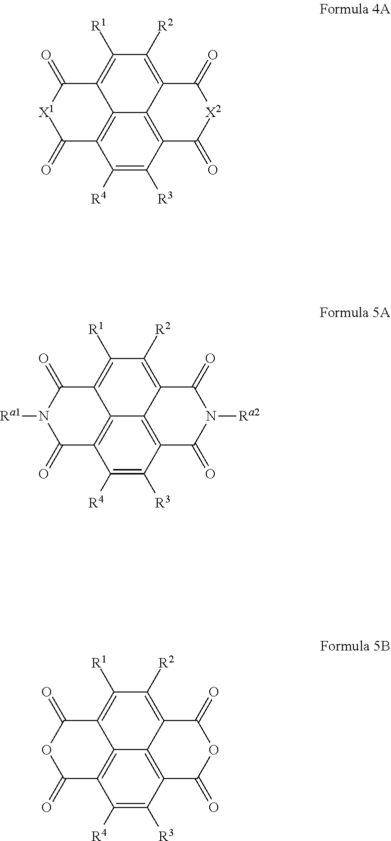

In Formula 4A above, X¹ and X² each are independently O or NR^{a}, R¹ to R⁴ and R^{a} each are independently hydrogen, a substituted or unsubstituted C1 to C30 alkyl group, a substituted or unsubstituted C6 to C30 aryl group, a substituted or unsubstituted C3 to C30 heterocyclic group, halogen, a cyano group, or a combination thereof.
Formula 4A may be expressed as Formula 5A or Formula 5B.

In Formulae 5A and 5B, R¹ to R⁴, R^{a1} and R^{a2} each are independently hydrogen, a substituted or unsubstituted C1 to C30 alkyl group, a substituted or unsubstituted C6 to C30 aryl group, a substituted or unsubstituted C3 to C30 heterocyclic group, halogen, a cyano group, or a combination thereof.

At least one of R^{a1} and R^{a2} may include an electron withdrawn group.

At least one of R^{a1} and R^{a2} may include halogen; a cyano group; a halogen substituted C1 to C30 alkyl group; a halogen substituted C6 to C30 aryl group; a halogen substituted C3 to C30 heterocyclic group; a cyano-substituted C1 to C30 alkyl group; a cyano-substituted C6 to C30 aryl group; a cyano-substituted C3 to C30 heterocyclic group; a substituted or unsubstituted pyridinyl group; a substituted or unsubstituted pyrimidinyl s group; a substituted or unsubstituted quinolinyl group; a substituted or unsubstituted isoquinolinyl group; a substituted or unsubstituted quinazolinyl group; a C1 to C30 alkyl group substituted with a substituted or unsubstituted pyridinyl group; a C6 to C30 aryl group substituted with a substituted or unsubstituted pyridinyl group; a C1 to C30 alkyl group substituted with a substituted or unsubstituted pyrimidinyl group; a C6 to C30 aryl group substituted with a substituted or unsubstituted pyrimidinyl group; a C1 to C30 alkyl group substituted with a substituted or unsubstituted triazinyl group; a C6 to C30 aryl group substituted with a substituted or unsubstituted triazinyl group; a C1 to C30 alkyl group substituted with a substituted or unsubstituted pyrazinyl group; a C6 to C30 aryl group substituted with a substituted or unsubstituted pyrazinyl group; a C1 to C30 alkyl group substituted with a substituted or unsubstituted quinolinyl group; a C6 to C30 aryl group substituted with a substituted or unsubstituted quinolinyl group; a C1 to C30 alkyl group substituted with a substituted or unsubstituted isoquinolinyl group; a C6 to C30 aryl group substituted with a substituted or unsubstituted isoquinolinyl group; a C1 to C30 alkyl group substituted with a substituted or unsubstituted quinazolinyl group; a C6 to C30 aryl group substituted with a substituted or unsubstituted quinazolinyl group; or combinations thereof.

The active layer 222c may generate excitons by receiving external light and separate the generated excitons into holes and electrons. When a positive potential is applied to the sensing electrode 221b and a negative potential is applied to the opposite electrode 223, the holes separated in the active layer 222c may move towards the opposite electrode 223, while the electrons separated in the active layer 222c may move towards the sensing electrode 221b. Therefore, a photocurrent may be formed in a direction from the sensing electrode 221b to the opposite electrode 223.

When a bias (e.g., the reset voltage VRST of FIG. 3) is applied between the sensing electrode 221b and the opposite electrode 223, a dark current may flow through the photodiode PD. In addition, when light is incident to the photodiode PD, the photocurrent may flow through the photodiode PD. In an embodiment, the light amount may be detected from a ratio of the photocurrent and the dark current.

The auxiliary layer 224 may be disposed above the light-emitting diode ED and the photodiode PD. For example, the auxiliary layer 224 may be disposed above the opposite electrode 223. The auxiliary layer 224 may decrease an energy barrier of the hole transport layer and the holes moving in an anode direction and facilitate the movement of the holes. The auxiliary layer 224 may include, for example, a fluorene-based compound, a carbazole-based compound, a diarylamine-based compound, a triarylamine-based compound, a dibenzofuran-based compound, a dibenzothiophene-based compound, a dibenzosilol-based compound, or any combination thereof.

The encapsulation layer 300 may be disposed above the light-emitting diode ED and the photodiode PD. For example, the encapsulation layer 300 may be arranged above the auxiliary layer 224. The encapsulation layer 300 may include at least one inorganic encapsulation layer and at least one organic encapsulation layer, and in an embodiment, FIG. 4 shows that the encapsulation layer 300 includes a first inorganic encapsulation layer 310, an organic encapsulation layer 320, and a second inorganic encapsulation layer 330 which are sequentially stacked.

The first inorganic encapsulation layer 310 and the second inorganic encapsulation layer 330 may each include one or more inorganic materials selected from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy-based resin, polyimide, polyethylene, and the like. In an embodiment, the organic encapsulation layer 320 may include acrylate. The organic encapsulation layer 320 may be formed by curing a monomer or applying a polymer. The organic encapsulation layer 320 may be transparent.

The input sensing layer 400 may be disposed above the encapsulation layer 300. The input sensing layer 400 may obtain coordinate information according to an external input, e.g., a touch event. The input sensing layer 400 may include a plurality of touch electrodes and a touch insulating layer.

The anti-reflection layer 500 may be disposed above the input sensing layer 400. The anti-reflection layer 500 may include a light-shielding layer BM, a first color filter CF1, and a second color filter CF2.

The light-shielding layer BM may be arranged above the input sensing layer 400. The light-shielding layer BM may at least partially absorb external or internal reflected light. The light-shielding layer BM may include a black pigment. The light-shielding layer BM may be a black matrix. The light-shielding layer BM may include a first light-shielding layer opening BOP1 disposed above the light-emitting diode ED and a second light-shielding layer opening BOP2 disposed above the photodiode PD. That is, the first light-shielding layer opening BOP1 may overlap the emission area EA, and the second light-shielding layer opening BOP2 may overlap the sensing area SA. The area of the first light-shielding layer opening BOP1 may be greater than or the same as the area of the first bank layer opening 2090P1 arranged in the bank layer 209. Also, the area of the second light-shielding layer opening BOP2 may be greater than or the same as the area of the second bank layer opening 2090P2 arranged in the bank layer 209.

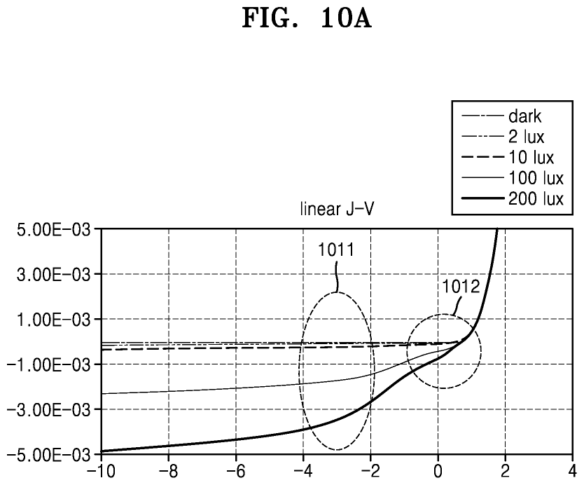

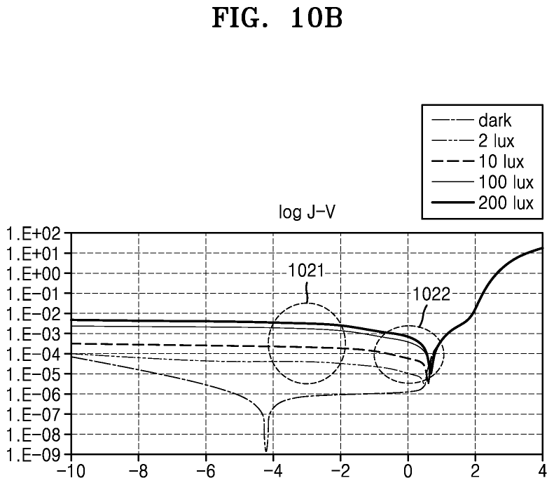

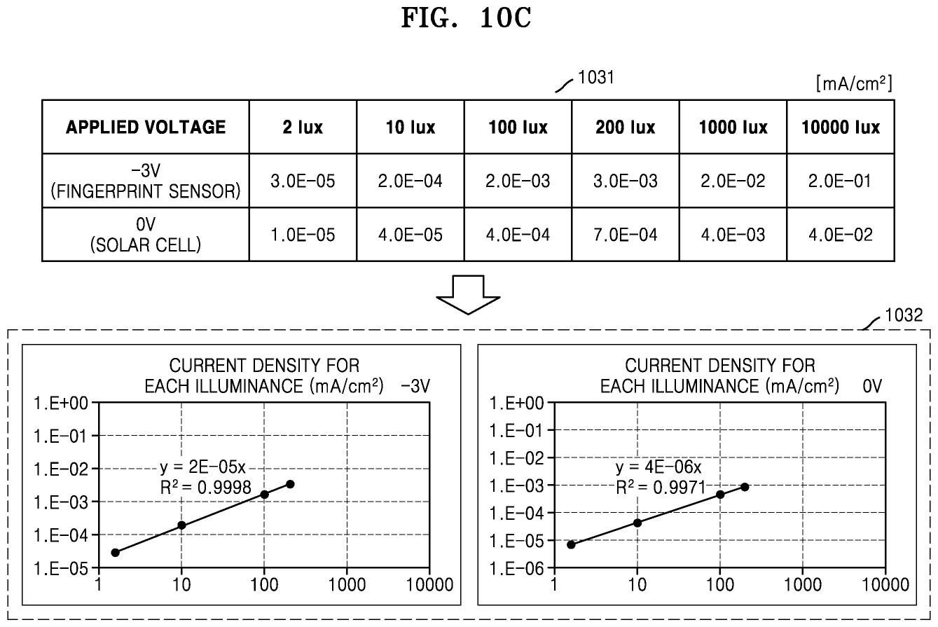

FIGS. 10A to 10C are diagrams for explaining that a photo sensor functions as a battery even when no voltage is applied, according to an embodiment.

FIGS. 10A and 10B are graphs respectively showing a relationship between a current density J and a bias B when illuminance is 0 lux (dark), 2 lux, 10 lux, 100 lux, and 200 lux. In the graphs of FIGS. 10A and 10B, the x axis may indicate the bias V applied, and the y axis may indicate the current density J in a linear scale (FIG. 10A) and a log scale (FIG. 10B).

Referring to FIGS. 10A and 10B, as a result of measuring a current when a bias is applied for each illuminance, it is found that, when there is a reverse bias of about −4 V to about 2 V, the photo sensor PS may function as a fingerprint detecting sensor in the second mode (1011 of FIG. 10A and 1021 of FIG. 10B) and even when no bias is applied (0 V), a current density is measured (1012 of FIG. 10A and 1022 of FIG. 10B). The third mode may still operate even in a state in which the photocurrent remains when there is no bias, no image data is received and no touch of the user is generated, that is, in a state in which the first mode and the second mode are not functioning. When the display apparatus 1 operates in the third mode, the fourth sensing transistor T11 is driven according to the sixth gate signal G6, and the photodiode PD generates carriers, including free electrons and holes, based on the intensity of light incident to a light-receiving layer, which results in the production of a photocurrent according to the movement of the carriers. The generated photocurrent may be input to the charge controller CC along the readout line RL, and the charge controller CC may control the received photocurrent, convert the same into a voltage, and deliver the voltage to the battery BT, and the battery may store the voltage.

Referring to FIG. 10C, when the bias is −3 V (which may indicate the operation in the second mode),a photocurrent may exist for each illuminance, and even when the bias is 0 V (which may indicate that the photo sensor PS operates as a battery in the third mode), the photocurrent for each illuminance is not equal to 0 mA/cm², and the current density may be 1.E-05 mA/cm² at 2 lux, 4.E-05 mA/cm² at 10 lux, 4.E-04 mA/cm² at 100 lux, 7.E-04 mA/cm² at 200 lux, 4.E-03 mA/cm² at 1000 lux, and 4.E-02 mA/cm² at 10000 lux, and thus, the photo sensor PS may function as a (solar) battery (1031). The graphs 1032 show a current density for each illuminance when the bias is −3 V and 0 V, respectively.

Processes of the method or algorithm described in relation to one or more embodiments of the disclosure may be directly implemented in hardware, software modules executed by hardware, or a combination thereof. The software module may be stored in random access memory (RAM), read only memory (ROM), erasable programmable ROM (EPROM), flash memory, hard disks, removable disks, CD-ROMs, or other forms of computer-readable recording medium well known in the art to which the disclosure pertains.

According to the one or more embodiments, a method of charging a display apparatus by using a light-receiving element may be provided.

According to the one or more embodiments, a display apparatus may function as a battery when no fingerprint is detected, according to the method of charging a display apparatus by using a light-receiving element.

Effects of the disclosure are not limited to those mentioned above, and other effects not mentioned may be clearly understood by one of ordinary skill in the art form the descriptions below.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a pixel arranged in a display area of the substrate and comprising a light-emitting diode configured to emit light in a first mode; and
a photo sensor arranged in the display area of the substrate and comprising a light-receiving element configured to receive light reflected from an external object in a second mode and receive external light in a third mode,
wherein the first mode is triggered by a signal to display an image, the second mode is triggered by a reflection from the external object, and the third mode is triggered by an absence of the signal to display an image and a reflection from the external object.

2. The display apparatus of claim 1, further comprising a readout circuit arranged on a peripheral area of the substrate and configured to process an electrical signal corresponding to an amount of the light received by the light-receiving element in the second mode.

3. The display apparatus of claim 2, further comprising:
a charge controller arranged on the peripheral area of the substrate and configured to store and control an electrical signal corresponding to an amount of the external light received by the light-receiving element in the third mode; and
a battery configured to store an output voltage of the charge controller.

4. The display apparatus of claim 1, wherein the light reflected from the external object comprises light emitted from the light-emitting diode in the second mode and then reflected off the external object,
wherein the light emitted from the light-emitting diode comprises green light.

5. The display apparatus of claim 2, wherein the photo sensor comprises a sensing circuit connected to the light-receiving element,
the light-receiving element comprises a first electrode, a second electrode, and an intermediate layer between the first electrode and the second electrode, and
the sensing circuit comprises:
a first transistor comprising a gate electrode connected to a first electrode of the light-receiving element;
a second transistor connected between the first transistor and a readout line connected to the readout circuit;
a reset transistor connected between a reset voltage line and the first electrode of the light-receiving element; and
a third transistor connected between the first electrode of the light-receiving element and the readout line.

6. The display apparatus of claim 5, wherein the reset transistor is turned on in response to a first reset signal in the second mode, the second transistor is turned on in response to a first control signal, and a photocurrent output from the first transistor is transmitted to the readout line.

7. The display apparatus of claim 6 wherein, in the third mode, the third transistor is turned on in response to a second reset signal, and a photocurrent corresponding to a voltage between the first electrode and a second electrode of the light-receiving element is transmitted to the readout line.

8. The display apparatus of claim 7, wherein the photo sensor operates in the third mode when the light-emitting diode included in the pixel is not emitting light and the photo sensor is not receiving the light reflected from the external object.

9. The display apparatus of claim 1, wherein the light-receiving element comprises an organic photodiode (OPD).

10. A display apparatus comprising:
a display panel comprising a plurality of pixels and a plurality of photo sensors;
a driving circuit configured to drive the plurality of pixels and the plurality of photo sensors;
a controller configured to control the display panel to display an image according to light emission from the plurality of pixels in a first mode, to control the plurality of photo sensors to sense light reflected from a fingerprint in a second mode, and to control external light sensed by the plurality of photo sensors to charge a battery in a third mode;
a readout circuit configured to receive a plurality of light sensing signals of the plurality of photo sensors and perform signal processing to obtain fingerprint information in the second mode; and
the battery configured to store a voltage corresponding to the plurality of light sensing signals of the plurality of photo sensors in the third mode.

11. The display apparatus of claim 10, further comprising a charge controller configured to control a voltage corresponding to the plurality of light sensing signals of the plurality of photo sensors in the third mode.

12. The display apparatus of claim 11, wherein the controller is configured to control the display apparatus to operate in the third mode in the absence of a signal to operate in the first mode or the second mode.

13. The display apparatus of claim 12, wherein the plurality of photo sensors and the charge controller are connected by a switch transistor that is turned on in response to a control signal from the controller.

14. A method of controlling operation of a display apparatus comprising a plurality of pixels and a plurality of photo sensors, the method comprising:
controlling the display apparatus to display an image according to light emission from the plurality of pixels in a first mode;
controlling the display apparatus to sense light reflected from an external object by using the plurality of photo sensors, and to process an electrical signal corresponding to an amount of the light in a second mode; and
controlling the display apparatus to sense external light by using the plurality of photo sensors and to charge a voltage corresponding to an amount of external light to charge a battery in a third mode.

15. The method of claim 14, wherein the controlling in the third mode comprises controlling the display apparatus to operate in the third mode in the absence of a signal to operate in either the first mode or the second mode.

16. The method of claim 14 wherein, in the second mode, light emitted from a plurality of first pixels among the plurality of pixels is reflected off the external object, wherein the plurality of first pixels are arranged adjacent to the external object and emit a certain color of light, and
the light emitted from the plurality of first pixels comprises green light.

17. The method of claim 14, wherein each of the plurality of photo sensors comprises a light-receiving element and a sensing circuit connected to the light-receiving element,
the light-receiving element comprises a first electrode, a second electrode, and an intermediate layer between the first electrode and the second electrode, and
the sensing circuit comprises:
a first transistor comprising a gate electrode connected to a first electrode of the light-receiving element;
a second transistor connected between the first transistor and a readout line connected to the readout circuit;
a reset transistor connected between a reset voltage line and the first electrode of the light-receiving element; and
a third transistor connected between the first electrode of the light-receiving element and the readout line.

18. The method of claim 17 further comprising, in the second mode, turning on the reset transistor in response to a first reset signal, turning on the second transistor in response to a first control signal, and transmitting a photocurrent that is output by the first transistor to the readout line.

19. The method of claim 18 further comprising, in the third mode, turning on the third transistor in response to a second reset signal, and transmitting a photocurrent corresponding to a voltage between the first electrode and the second electrode of the light-receiving element to the readout line.

20. The method of claim 17, wherein the light-receiving element comprises an organic photodiode (OPD).
